(19) United States
(12) Patent Application Publication
(10) Pub. No.: US 2026/0033066 A1
(43) Pub. Date: Jan. 29, 2026

(54) DISPLAY APPARATUS INCLUDING A REPAIR BRIDGE PATTERN AND ELECTRONIC APPARATUS INCLUDING THE SAME

(71) Applicant: SAMSUNG DISPLAY CO., LTD., YONGIN-SI (KR)

(72) Inventors: Hyunae Park, YONGIN-SI (KR); Sujin Kim, YONGIN-SI (KR); Kwangjin Yong, YONGIN-SI (KR); Hyunbae Choi, YONGIN-SI (KR)

(21) Appl. No.: 19/277,693

(22) Filed: Jul. 23, 2025

(30) Foreign Application Priority Data
Jul. 23, 2024 (KR) 10-2024-0097495
Mar. 7, 2025 (KR) 10-2025-0029949

(51) Int. Cl. H10H 29/39; H10D 86/40; H10H 29/49

(52) U.S. Cl. CPC H10H 29/39; H10D 86/423; H10H 29/49

(57) ABSTRACT

A display apparatus includes a substrate, a first pixel circuit disposed on the substrate and including a driving transistor and a storage capacitor, a light emitting diode electrically connected to the first pixel circuit, and a repair line disposed on the substrate and extending in a first direction. The first pixel circuit further includes a first pixel connection electrode electrically connected to a pixel electrode of the light emitting diode, and a repair bridge pattern disposed between the repair line and the first pixel connection electrode. In a plan view, the repair bridge pattern overlaps each of the repair line and the first pixel connection electrode.

### CROSS-REFERENCE TO RELATED APPLICATION

The present application claims priority under 35 U.S.C. § 119 to Korean Patent Application No. 10-2024-0097495, filed on Jul. 23, 2024, and 10-2025-0029949 filed on Mar. 7, 2025, in the Korean Intellectual Property Office, the entire contents of which are herein incorporated by reference.

### TECHNICAL FIELD

The present disclosure relates to a display apparatus and, more specifically, to a display apparatus including a repair bridge pattern an electronic apparatus including the same.

### DISCUSSION OF THE RELATED ART

Display apparatuses are now used for a wide range of applications, and as their use has become more widespread, the demand for high-resolution displays has grown. To achieve higher resolution, it is often necessary to arrange electronic components with diverse configurations within increasingly limited spaces.

### SUMMARY

According to an embodiment of the disclosure, a display apparatus includes a substrate, a first pixel circuit disposed on the substrate and including a driving transistor and a storage capacitor, a light emitting diode electrically connected to the first pixel circuit, and a repair line disposed on the substrate and extending in a first direction. The first pixel circuit further includes a first pixel connection electrode electrically connected to a pixel electrode of the light emitting diode, and a repair bridge pattern disposed between the repair line and the first pixel connection electrode, and in a plan view, the repair bridge pattern overlaps each of the repair line and the first pixel connection electrode.

In an embodiment, the first pixel circuit may further include a first conductive pattern disposed on the substrate and including a first electrode of the storage capacitor, a second conductive pattern disposed on the first conductive pattern and overlapping the first conductive pattern and including a second electrode of the storage capacitor, a third conductive pattern disposed on the second conductive pattern and including a lower gate electrode of the driving transistor, a first semiconductor pattern disposed on the third conductive pattern and including a semiconductor layer of the driving transistor, and a fourth conductive pattern disposed on the first semiconductor pattern and including an upper gate electrode of the driving transistor.

In an embodiment, the repair line may be disposed on the same layer as the first conductive pattern or the second conductive pattern, and the repair bridge pattern may be disposed on the same layer as the third conductive pattern.

In an embodiment, the first semiconductor pattern may include an oxide semiconductor material.

In an embodiment, the first pixel circuit may further include a fifth conductive pattern disposed on the fourth conductive pattern and disposed on the same layer as the first pixel connection electrode, and a second semiconductor pattern disposed on the same layer as the first semiconductor pattern, connected to the fifth conductive pattern, and including a semiconductor layer of an emission control transistor.

In an embodiment, in a plan view, a first portion of the first pixel connection electrode may overlap the second semiconductor pattern, and a second portion of the first pixel connection electrode may overlap the repair bridge pattern.

In an embodiment, the first pixel circuit may further include a second pixel connection electrode disposed on the first pixel connection electrode and connecting the first pixel connection electrode and the light emitting diode to each other, and the first pixel connection electrode and the second pixel connection electrode may electrically connect the second semiconductor pattern and the light emitting diode to each other.

In an embodiment, the display apparatus may further include a plurality of voltage lines disposed on the substrate and extending in the first direction or a second direction intersecting the first direction. The first pixel circuit may further include a dummy line disposed on the same layer as the repair bridge pattern and extending in the first direction, and the dummy line may be electrically connected to at least one of the plurality of voltage lines.

In an embodiment, the plurality of voltage lines may include a reference voltage line extending in the first direction, the first pixel circuit may further include a reference transistor connected between the driving transistor and the reference voltage line, and the dummy line may be electrically connected to the reference voltage line.

In an embodiment, the reference voltage line may include an upper reference voltage line disposed on the same layer as the first pixel connection electrode, and the dummy line may be connected to the upper reference voltage line through a contact hole.

In an embodiment, the reference voltage line may further include a lower reference voltage line disposed under the upper reference voltage line, and the lower reference voltage line may include a silicon semiconductor material.

In an embodiment, the plurality of voltage lines may include a common voltage line extending in the first direction and electrically connected to the light emitting diode, and the dummy line may be electrically connected to the common voltage line.

In an embodiment, the plurality of voltage lines may include a driving voltage line extending in the first direction, the first pixel circuit may further include a driving control transistor connected between the driving transistor and the driving voltage line, and the dummy line may be electrically connected to the driving voltage line.

In an embodiment, the plurality of voltage lines may include an initialization voltage line extending in the first direction, the first pixel circuit may further include an emission control transistor connected between the driving transistor and the light emitting diode, and an initialization transistor connected between the emission control transistor and the initialization voltage line, and the dummy line may be electrically connected to the initialization voltage line.

According to an embodiment of the disclosure, a display apparatus includes a substrate, a first pixel circuit disposed on the substrate and including a first transistor and a storage capacitor, a light emitting diode electrically connected to the first pixel circuit, and a plurality of voltage lines disposed on the substrate and extending in a first direction. The first pixel circuit further includes a first conductive pattern including a lower gate electrode of the first transistor, and a dummy line disposed on the same layer as the first conductive pattern and extending in the first direction, and the dummy line is electrically connected to at least one of the plurality of voltage lines.

In an embodiment, the display apparatus may further include a data line extending in a second direction intersecting the first direction and connected to the first pixel circuit. The plurality of voltage lines may include a reference voltage line extending in the first direction, the first pixel circuit may further include a second transistor connected between the data line and the first transistor, and a third transistor connected between the reference voltage line and the first transistor, and the dummy line may be electrically connected to the reference voltage line.

In an embodiment, the plurality of voltage lines may include a common voltage line extending in the first direction and electrically connected to the light emitting diode, and the dummy line may be electrically connected to the common voltage line.

In an embodiment, the plurality of voltage lines may include an initialization voltage line extending in the first direction, the first pixel circuit may further include a fourth transistor connected between the initialization voltage line and the light emitting diode, and the dummy line may be electrically connected to the initialization voltage line.

In an embodiment, the plurality of voltage lines may include a driving voltage line extending in the first direction, the first pixel circuit may further include a fifth transistor connected between the driving voltage line and the first transistor, and the dummy line may be electrically connected to the driving voltage line.

In an embodiment, a semiconductor layer of the first transistor and a semiconductor layer of the fifth transistor may be disposed on different layers.

In an embodiment, the display apparatus may further include a repair line disposed on the substrate and extending in the first direction. The first pixel circuit may further include a first pixel connection electrode electrically connected to a pixel electrode of the light emitting diode, and a repair bridge pattern disposed between the repair line and the first pixel connection electrode and disposed on the same layer as the first conductive pattern, and in a plan view, the repair bridge pattern may overlap each of the repair line and the first pixel connection electrode.

In an embodiment, the first pixel circuit may further include a second conductive pattern disposed on the substrate and including a first electrode of the storage capacitor, and a third conductive pattern disposed on the second conductive pattern and including a second electrode of the storage capacitor, and the repair line may be disposed on the same layer as the second conductive pattern or the third conductive pattern.

According to an embodiment of the disclosure, an electronic apparatus includes a display apparatus. The display apparatus includes a substrate, a first pixel circuit disposed on the substrate and including a driving transistor and a storage capacitor, a light emitting diode electrically connected to the first pixel circuit, and a repair line disposed on the substrate and extending in a first direction. The first pixel circuit further includes a first pixel connection electrode electrically connected to a pixel electrode of the light emitting diode, and a repair bridge pattern disposed between the repair line and the first pixel connection electrode, and in a plan view, the repair bridge pattern overlaps each of the repair line and the first pixel connection electrode.

### BRIEF DESCRIPTION OF DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view schematically illustrating a display apparatus according to an embodiment of the disclosure;

FIG. 2 is a side view schematically illustrating a display apparatus according to an embodiment of the disclosure;

FIG. 3 is a plan view schematically illustrating a display apparatus according to an embodiment of the disclosure;

FIG. 4A is a diagram schematically illustrating a portion of a display apparatus according to an embodiment of the disclosure;

FIG. 4B is a diagram for describing a method of repairing a defective pixel in a display apparatus according to an embodiment of the disclosure;

FIG. 5 is an equivalent circuit diagram of a light emitting diode and a pixel circuit of a display apparatus according to an embodiment of the disclosure;

FIG. 6 is a plan view schematically illustrating pixel circuits of a display apparatus according to an embodiment of the disclosure;

FIG. 7 is a schematic cross-sectional view of a display apparatus according to an embodiment of the disclosure and illustrates a cross-section taken along line VII-VII′ of FIG. 3;

FIGS. 8 to 15 are plan views illustrating a process of forming a pixel circuit of a display apparatus according to an embodiment of the disclosure;

FIGS. 16A and 16B are plan views schematically illustrating pixel circuits of a display apparatus according to an embodiment of the disclosure;

FIGS. 17A and 17B are plan views schematically illustrating pixel circuits of a display apparatus according to an embodiment of the disclosure;

FIGS. 18A and 18B are plan views schematically illustrating pixel circuits of a display apparatus according to an embodiment of the disclosure;

FIG. 19 is a block diagram of an electronic apparatus according to an embodiment of the disclosure; and

FIG. 20 is a schematic diagram of electronic apparatuses according to various embodiments of the disclosure.

### DETAILED DESCRIPTION OF THE DRAWINGS

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, the disclosure is not necessarily limited to the embodiments described below and may be implemented in various forms.

Hereinafter, embodiments of the disclosure will be described in detail with reference to the accompanying drawings, and in the following description, like reference numerals may denote like elements throughout the specification and the drawings and to the extent that an element is not described in detail with respect to this figure, it may be understood that the element is at least similar to a corresponding element that has been described elsewhere within the present disclosure.

It will be understood that although terms such as “first” and “second” may be used herein to describe various elements, these elements should not necessarily be limited by these terms and these terms are used to distinguish one element from another element.

As used herein, the singular forms “a,” “an,” and “the” are intended to include the plural forms as well, unless the context clearly indicates otherwise.

It will be understood that terms such as “comprise,” “include,” and “have” used herein specify the presence of stated features or elements, but do not preclude the presence or addition of one or more other features or elements.

It will be understood that when a layer, region, or component is referred to as being “on” another layer, region, or component, it may be “directly on” the other layer, region, or component or may be “indirectly on” the other layer, region, or component with one or more intervening layers, regions, or components interposed therebetween.

Sizes of components in the drawings may be exaggerated for convenience of description. For example, because the sizes and shapes of components in the drawings are arbitrarily illustrated for convenience of description, the disclosure is not necessarily limited thereto.

When a certain embodiment may be implemented differently, a particular process order may be performed differently from the described order. For example, two consecutively described processes may be performed substantially at the same time or performed in an order opposite to the described order.

It will be understood that when a layer, region, area, component, or element is referred to as being “connected to” another layer, region, area, component, or element, it may be “directly connected to” the other layer, region, area, component, or element or may be “indirectly connected to” the other layer, region, area, component, or element with one or more intervening layers, regions, areas, components, or elements interposed therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components interposed therebetween.

Embodiments of the present disclosure relate to a display apparatus design that includes a repair bridge pattern to enhance reliability, manufacturability, and repairability, particularly in high-resolution electronic displays such as OLED panels.

The display apparatus may include a substrate on which pixel circuits are arranged. Each pixel circuit contains a driving transistor, a storage capacitor, and a light emitting diode (LED) that is electrically connected to the circuit. A key innovation is the integration of a repair line alongside a repair bridge pattern. The repair bridge pattern physically overlaps both the repair line and the first pixel connection electrode in a plan view, providing a simplified and efficient means for repairing defective pixel circuits after manufacturing.

The structure of each pixel circuit is carefully layered, comprising multiple conductive patterns and semiconductor patterns that are vertically stacked and interconnected. The repair line may reside on the same layer as lower conductive patterns, while the repair bridge pattern is aligned with higher conductive patterns such as gate electrodes. This arrangement enables targeted laser repair, allowing defective pixel circuits to be disconnected and replaced with operational circuits via the dummy lines and repair bridges. The use of oxide semiconductors in the transistor layers contributes to achieving high electron mobility and low leakage, supporting the performance demands of modern displays.

Additionally, the apparatus includes dummy circuits and dummy lines that are strategically connected to voltage lines. These dummy structures enable rerouting of signals and voltages around defective pixels without modifying the main data driving schemes. The design supports repairs by creating easily accessible electrical pathways that can be connected or disconnected post-manufacture through laser processing, which melts insulating layers or conductive bridges at designated points.

In broader application, this display apparatus can be incorporated into foldable or flexible electronic devices, enhancing the durability and longevity of such devices by allowing easier in-field repairs and defect management. The layered construction and repair-oriented architecture represent a robust solution for maintaining high production yields and ensuring high display quality in commercial electronics.

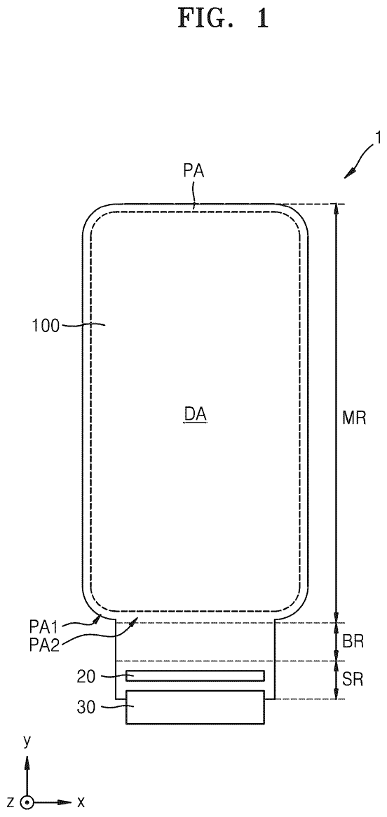

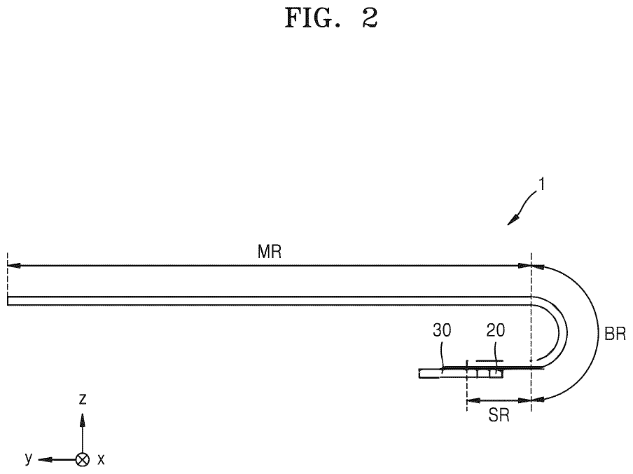

FIG. 1 is a plan view schematically illustrating a display apparatus 1 according to an embodiment of the disclosure, and FIG. 2 is a side view schematically illustrating a display apparatus 1 according to an embodiment of the disclosure.

The display apparatus 1 may include a display area DA and a peripheral area PA outside the display area DA. The display area DA may be an area for displaying an image, and a plurality of pixels may be disposed in the display area DA. For example, the display area DA may have any of various shapes such as a circular shape, an elliptical shape, a polygonal shape, and a particular figure shape. For example, FIG. 1 illustrates that the display area DA has a substantially rectangular shape with rounded corners.

The peripheral area PA may be disposed outside the display area DA. The peripheral area PA may include a first peripheral area PA1 surrounding at least a portion of the display area DA and a second peripheral area PA2 located adjacent to one side of the display area DA and extending in a second direction (e.g., y-axis direction). The width of the second peripheral area PA2 in a first direction (e.g., x-axis direction) may be less than the width of the display area DA. Through this structure, at least a portion of the second peripheral area PA2 may be easily bent.

The planar shape of the display apparatus 1 illustrated in FIG. 1 may be substantially the same as the shape of a substrate 100 included in the display apparatus 1. When the display apparatus 1 includes the display area DA and the peripheral area PA outside the display area DA, it may be considered that the substrate 100 includes the display area DA and the peripheral area PA outside the display area DA. Hereinafter, for convenience, it will be described that the substrate 100 includes the display area DA and the peripheral area PA.

The display apparatus 1 may include a main region MR, a bending region BR outside the main region MR, and a sub-region SR spaced apart from the main region MR with the bending region BR interposed therebetween. The main region MR may be disposed on one side of the bending region BR, and the sub-region SR may be disposed on the other side of the bending region BR. The display apparatus 1 may be bent in the bending region BR as illustrated in FIG. 2, and at least a portion of the sub-region SR may overlap the main region MR when viewed in a third direction (e.g., z-axis direction). Although FIG. 2 illustrates that the display apparatus 1 is bent, the disclosure is not necessarily limited thereto. In an embodiment, the display apparatus 1 may be a foldable display apparatus, and the display area DA may be bent around a bending axis intersecting the display area DA. In an embodiment, the display apparatus 1 might not be bent. The sub-region SR may be a non-display area.

A data driver 20 may be disposed in the sub-region SR of the display apparatus 1. The data driver 20 may be disposed in the display apparatus 10 in the form of an integrated circuit (IC). For example, the data driver 20 may be a data driving IC that generates a data signal.

A display circuit board 30 may be attached to an end portion of the sub-region SR of the display apparatus 1. The display circuit board 30 may be electrically connected to the data driver 20 or the like through a pad of the sub-region SR of the display apparatus 1.

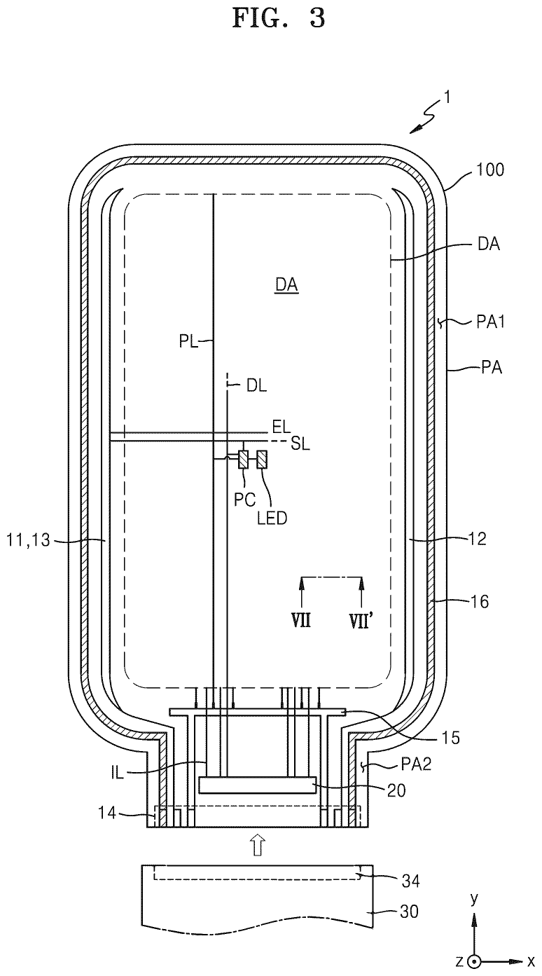

FIG. 3 is a plan view schematically illustrating a display apparatus 1 according to an embodiment of the disclosure.

Referring to FIG. 3, the display apparatus 1 may include a substrate 100. Various components included in the display apparatus 1 may be disposed on the substrate 100.

The substrate 100 may include glass, metal, or polymer resin. The substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers including the polymer resin and an inorganic layer disposed between the two layers.

Pixels may be disposed in the display area DA, and the display area DA may provide an image by using light emitted from the pixels. Each pixel may include a light emitting diode LED, and the light emitting diode LED may be electrically connected to a pixel circuit PC. The pixel circuit PC and the light emitting diode LED may be disposed in the display area DA.

A gate driving circuit (e.g., a first scan driving circuit 11 and a second scan driving circuit 12), an emission control driving circuit 13, a pad 14, a first power supply line 15, a second power supply line 16 may be disposed in the peripheral area PA.

The first scan driving circuit 11 may provide a scan signal to the pixel circuit PC through a gate line SL. The second scan driving circuit 12 may be disposed on the opposite side of the first scan driving circuit 11 with the display area DA interposed therebetween. Some of the pixel circuits PC disposed in the display area DA may be electrically connected to the first scan driving circuit 11, and the others may be connected to the second scan driving circuit 12. In an embodiment, the second scan driving circuit 12 may be omitted.

The emission control driving circuit 13 may be disposed on the side of the first scan driving circuit 11 and may provide an emission control signal to a pixel P through an emission control line EL. FIG. 3 illustrates that the emission control driving circuit 13 is disposed only on one side of the display area DA; however, the disclosure is not necessarily limited thereto. In an embodiment, emission control driving circuits 13 may be disposed on both sides of the display area DA.

The pad 14 may be disposed in the second peripheral area PA2 of the substrate 100. The pad 14 may be in an exposed state by not being covered by an insulating layer and may be electrically connected to the display circuit board 30. A pad 34 of the display circuit board 30 may be electrically connected to the pad 14 of the display apparatus 1.

The display circuit board 30 may transmit a signal or power of a controller to the display apparatus 1. A control signal generated by the controller may be transmitted to each gate driving circuit through the display circuit board 30. Also, the controller may provide a driving voltage and a common voltage to the first and second power supply lines 15 and 16 respectively. The driving voltage may be provided to each pixel circuit PC through a driving voltage line PL connected to the first power supply line 15, and the common voltage may be provided to an opposite electrode of the light emitting diode LED connected to the second power supply line 16. The first power supply line 15 may extend in the first direction (e.g., x-axis direction). The second power supply line 16 may have a loop shape with one side open and thus may partially surround the display area DA.

A data signal of the data driver 20 may be transmitted to the pixel circuit PC through an input line IL and a data line DL electrically connected to the input line IL.

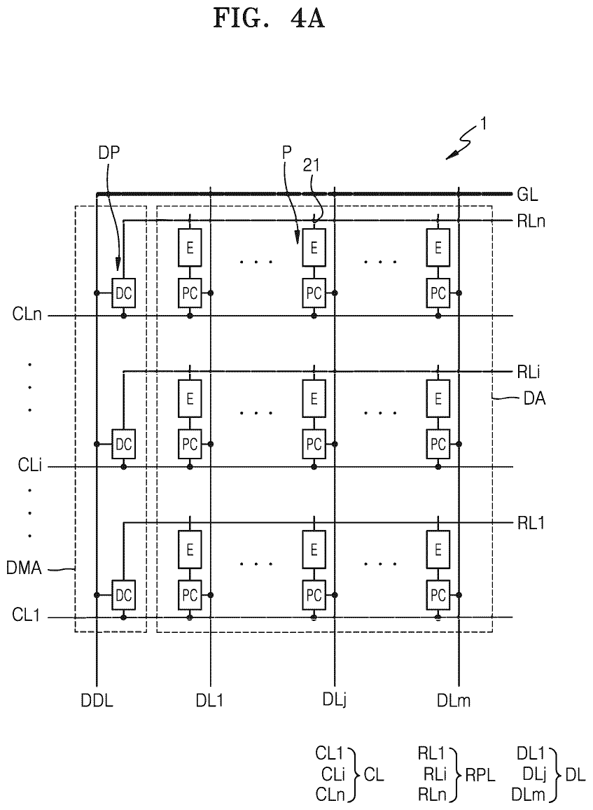

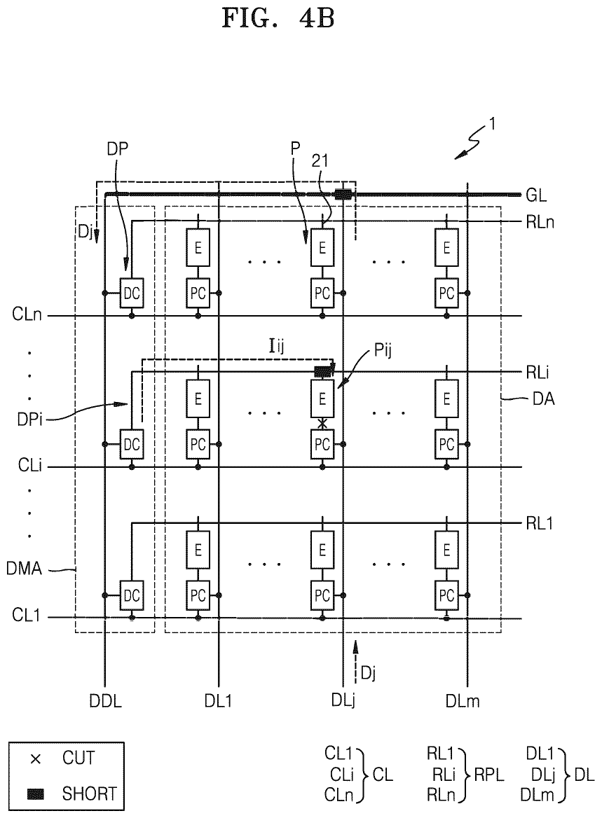

FIG. 4A is a diagram schematically illustrating a portion of a display apparatus according to an embodiment of the disclosure.

Referring to FIG. 4A, the display apparatus 1 may include a display area DA for displaying an image by light emission and a dummy area DMA around the display area DA. The dummy area DMA may be disposed in the peripheral area PA (see FIG. 3) or may be an area outside the display area DA.

A pixel P disposed in the display area DA may include a pixel circuit PC and a light emitting element E that emits light by receiving a driving current from the pixel circuit PC. Here, the light emitting element E may include the light emitting diode LED of FIG. 3. The light emitting element E and the pixel circuit PC may be detachably connected to each other. The pixel circuit PC may include one or more thin film transistors and a capacitive element. Herein, the capacitive element may refer to a capacitor. The pixel P may emit light of one color and may emit, for example, light of one color among red, blue, green, and white. However, the disclosure is not necessarily limited thereto, and the pixel P may emit light of other colors than red, blue, green, and white.

A control line CL, a repair line RPL, and a data line DL may be disposed in the display area DA and the dummy area DMA. A pixel P of the display area DA may be connected to each of a control line CL extending in the first direction (e.g., x-axis direction) and a data line DL extending in the second direction (e.g., y-axis direction). Likewise, a dummy pixel P of the dummy area DMA may be connected to each of a control line CL extending in the first direction (e.g., x-axis direction) and a dummy data line DDL extending in the second direction (e.g., y-axis direction). In FIG. 4A, for convenience, the control line CL is illustrated as a single signal line; however, the control line CL may include a plurality of signal lines. For example, the control line CL may include the gate line SL (see FIG. 3) and the emission control line EL (see FIG. 3).

Moreover, the display apparatus 1 may further include a connection line GL to which the dummy data line DDL and the data line DL are connected. The connection line GL may extend in the first direction (e.g., x-axis direction). The connection line GL may be disposed in a dead space outside the display area DA and the dummy area DMA. The connection line GL and the data line DL may be insulated from each other, and the data line DL and one of the connection lines GL may be electrically connected to each other in a repair process.

The dummy pixel DP disposed in the dummy area DMA may include a dummy circuit DC. For example, when the pixel P illustrated in FIG. 2 is a defective pixel, the light emitting element E of the defective pixel may be separated from the pixel circuit PC of the defective pixel and connected to the corresponding dummy pixel DP through the repair line RPL. Also, among the data lines DL, a data line DL connected to the defective pixel may be connected to the dummy data line DDL through the connection line GL. A data signal applied to the defective pixel may be applied to the dummy pixel DP through the data line DL, the connection line GL connected to the data line DL, and the dummy data line DDL connected to the connection line GL. The dummy pixel DP may generate a driving current corresponding to the data signal and supply the driving current to the light emitting element E of the defective pixel through the repair line RPL. The light emitting element E may emit light of a brightness corresponding to the data signal. Thus, the light emitting element E of the defective pixel may operate normally by the dummy pixel DP.

The light emitting element E of the pixel P may be insulated from the repair line RPL of the same row and may be electrically connected to the repair line RPL in a later repair process. For example, the light emitting element E of the pixel P may be connectable to the repair line RPL of the same row. For example, the light emitting element E may be electrically connected to a first connection member 21, and the first connection member 21 may partially overlap the repair line RPL with an insulating layer interposed therebetween. The first connection member 21 may include one or more conductive layers including a conductive material. In a repair process, when a laser beam is cast to an overlap area of the first connection member 21 and the repair line RPL, the insulating layer may be destroyed and the first connection member 21 and the repair line RPL may be short-circuited and electrically connected to each other. Accordingly, the light emitting element E may be electrically connected to the repair line RPL.

The dummy pixel DP may include a dummy circuit DC and might not include a light emitting element. The dummy circuit DC may be equal to the pixel circuit PC. In an embodiment, the dummy circuit DC may be different from the pixel circuit PC. For example, the dummy circuit DC may correspond to the omission or addition of the transistors and/or the capacitive element of the pixel circuit PC or may be different in the sizes and characteristics of the transistors and the capacitive element from the pixel circuit PC.

Herein, the term “connectable” or “connectably” may mean the state of being connectable to each other in the repair process by using a laser beam or the like. For example, that a first member and a second member are connectably disposed may mean that the first member and the second member are not actually connected but are in the state of being connectable to each other in the repair process. From a structural viewpoint, the first member and the second member that are “connectable” to each other may intersect each other with an insulating layer interposed therebetween in an overlap area thereof. When a laser beam is cast to the overlap area in the repair process, the insulating layer in the overlap area may be destroyed and the first member and the second member may be electrically connected to each other.

Also, herein, the term “detachable” or “detachably” may mean the state of being detachable from each other in the repair process by using a laser beam or the like. For example, that a first member and a second member are detachably connected to each other may mean that the first member and the second member are actually connected to each other but are in the state of being detachable from each other in the repair process. From a structural viewpoint, the first member and the second member detachably connected to each other may be connected to each other through a conductive connection member. When a laser beam is cast to the conductive connection member in the repair process, as a portion irradiated with the laser beam is melted, the conductive connection member may be cut and the first member and the second member may be electrically insulated from each other. For example, the conductive connection member may include a silicon layer that may be melted by a laser beam. As an example, the conductive connection member may be cut by being melted by Joule heat generated by a current.

FIG. 4B is a diagram for describing a method of repairing a defective pixel in a display apparatus according to an embodiment of the disclosure.

Referring to FIG. 4B, a case where a defect occurs in a pixel Pij connected to an (i)th control line CLi and a (j)th data line DLj among the pixels P included in the display area DA, for example, a case where a pixel circuit PC of the pixel Pij is defective will be described as an example. In the present example, the pixel Pij will be referred to as a defective pixel Pij. The pixel Pij may be a pixel located in an (i)th row and a (j)th column. Here, i and j may be positive integers.

Referring to FIG. 4B, a light emitting element E of the defective pixel Pij may be separated from the pixel circuit PC. For example, by casting a laser beam to a connection area between the light emitting element E and the pixel circuit PC to cut the connection area, the light emitting element E of the defective pixel Pij may be separated from the pixel circuit PC.

Next, the light emitting element E of the defective pixel Pij and a dummy circuit DC of a dummy pixel DPi may be electrically connected to each other. For this purpose, the light emitting element E of the defective pixel Pij may be connected to a repair line RLi of the same row. For example, by casting a laser beam to an overlap area of the first connection member 21 connected to the light emitting element E of the defective pixel Pij and the repair line RLi of the same row, the light emitting element E may be electrically connected to the repair line RLi. Because the repair line RLi is connected to the dummy circuit DC, the light emitting element E of the defective pixel Pij may be connected to the dummy circuit DC of the dummy pixel DPi.

Next, the dummy data line DDL and the data line DLj connected to the defective pixel Pij may be electrically connected to each other. For this purpose, the data line DLj may be connected to the connection line GL. For example, by casting a laser beam to an overlap area of the data line DLj and the connection line GL, the data line DLj and the connection line GL may be electrically connected to each other. Because the connection line GL is connected to the dummy data line DDL, the data line DLj and the dummy data line DDL may be connected to each other.

The pixel circuit PC of the defective pixel Pij and the dummy circuit DC of the dummy pixel DPi may simultaneously respond to a scan signal applied through the same scan line among the control lines CLi. Because the data line DLj connected to the pixel circuit PC of the defective pixel Pij is connected to the dummy data line DDL through the connection line GL, a data signal Dj applied to the pixel circuit PC of the defective pixel Pij may also be applied to the dummy circuit DC of the dummy pixel DPi. The dummy circuit DC may generate a driving current Iij corresponding to the data signal Dj and may provide the driving current Iij to the light emitting element E of the defective pixel Pij through the repair line RLi. The light emitting element E of the defective pixel Pij may emit light with a brightness corresponding to the data signal Dj by the driving current Iij. Accordingly, the defective pixel Pij may be repaired as a normal pixel.

In the present example, because the dummy data line DDL is connected to the data line DLj through the connection line GL, the dummy data line DDL might not need to be separately driven. Thus, in order to provide a separate timing or drive the dummy data line DDL, a source driver might not need to be modified and an existing driver may be used as it is.

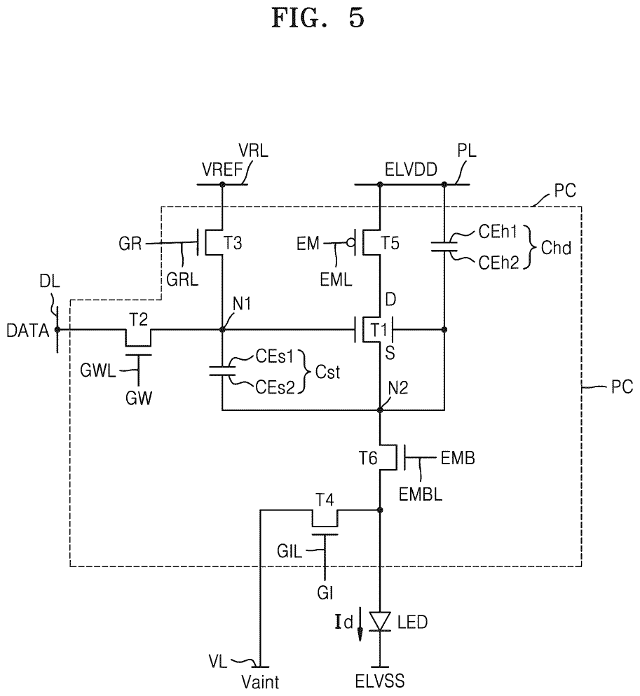

FIG. 5 is an equivalent circuit diagram of a light emitting diode LED and a pixel circuit PC of a display apparatus according to an embodiment of the disclosure.

Referring to FIG. 5, a pixel circuit PC connected to the light emitting diode LED may include a plurality of transistors and a plurality of capacitors. In an embodiment, the pixel circuit PC may include first to sixth transistors T1, T2, T3, T4, T5, and T6, a storage capacitor Cst, and a hold capacitor Chd. The first transistor T1 may be a driving transistor outputting a driving current corresponding to a data signal, and the second to sixth transistors T2, T3, T4, T5, and T6 may be switching transistors configured to transmit signals. A first terminal (e.g., first electrode) of each of the first to sixth transistors T1, T2, T3, T4, T5, and T6 may be a source or a drain, and a second terminal (e.g., second electrode) thereof may be a terminal different from the first terminal. For example, when the first terminal is a drain, the second terminal may be a source.

In an embodiment, at least one of the first to sixth transistors T1, T2, T3, T4, T5, and T6 may be p-channel MOSFETs (PMOSs), and the others may be n-channel MOSFETs (NMOSs). For example, the fifth transistor T5 may be a PMOS, and the first, second, third, fourth, and sixth transistors T1, T2, T3, T4, and T6 may be NMOSs. In an embodiment, the fifth transistor T5 and the sixth transistor T6 may be PMOSs, and the first, second, third, and fourth transistors T1, T2, T3, and T4 may be NMOSs. Alternatively, all of the first to sixth transistors T1, T2, T3, T4, T5, and T6 may be NMOSs or may be PMOSs. Hereinafter, an embodiment in which the fifth transistor T5 is a PMOS including a silicon semiconductor and the first, second, third, fourth, and sixth transistors T1, T2, T3, T4, and T6 are NMOSs including an oxide semiconductor will be mainly described.

At least one of the plurality of transistors T1, T2, T3, T4, T5, and T6 may be a transistor including a low-temperature polycrystalline silicon (LTPS) semiconductor layer, and at least one of the plurality of transistors T1, T2, T3, T4, T5, and T6 may be a transistor including an oxide semiconductor layer. For example, the fifth transistor T5 may include a semiconductor layer including polycrystalline silicon having high reliability, and the first, second, third, fourth, and sixth transistors T1, T2, T3, T4, and T6 may include an oxide semiconductor layer having high carrier mobility and low leakage current.

The pixel circuit PC may be electrically connected to a gate line configured to transmit a signal to a gate of each of the first to sixth transistors T1, T2, T3, T4, T5, and T6. For example, the pixel circuit PC may be connected to a scan line GWL configured to transmit a scan signal GW, an initialization gate line GIL configured to transmit an initialization signal GI, a reference gate line GRL configured to transmit a reference signal GR, a first emission control line EML configured to transmit a first emission control signal EM, a second emission control line EMBL configured to transmit a second emission control signal EMB, and a data line DL configured to transmit a data signal DATA. Also, the pixel circuit PC may be connected to a driving voltage line PL configured to transmit a driving voltage ELVDD, a reference voltage line VRL configured to transmit a reference voltage Vref, and an initialization voltage line VL configured to transmit an initialization voltage Vaint.

The first transistor T1 may be electrically connected between the driving voltage line PL and a second node N2. The first transistor T1 may include a gate connected to a first node N1, a first terminal connected to the driving voltage line PL, and a second terminal connected to the second node N2. The first terminal may be a drain D and the second terminal may be a source S. The first transistor T1 may have a dual-gate structure. In addition to the gate connected to the first node N1, the first transistor T1 may further include a lower gate electrode overlapping a channel area of the first transistor T1. The lower gate electrode may be connected to the second node N2 and a second hold electrode CEh2 of the hold capacitor Chd.

The first terminal of the first transistor T1 may be connected to the driving voltage line PL via the fifth transistor T5, and the second terminal of the first transistor T1 may be connected to a pixel electrode of the light emitting diode LED. The first transistor T1 may receive a data signal DATA according to a switching operation of the second transistor T2 to control the amount of a driving current Id flowing through the light emitting diode LED.

The second transistor T2 may be electrically connected between the data line DL and the first node N1. The second transistor T2 may include a gate connected to the scan line GWL, a first terminal connected to the data line DL, and a second terminal connected to the first node N1. The second transistor T2 may be turned on by the scan signal GW received through the scan line GWL, to electrically connect the data line DL with the first node N1 and transmit the data signal DATA received through the data line DL, to the first node N1.

The third transistor T3 may be electrically connected to the first node N1 and the reference voltage line VRL. The third transistor T3 may include a gate connected to the reference gate line GRL, a first terminal connected to the first node N1, and a second terminal connected to the reference voltage line VRL. The third transistor T3 may be turned on by the reference signal GR received through the reference gate line GRL, to transmit the reference voltage Vref received through the reference voltage line VRL, to the first node N1. The third transistor T3 may also be referred to as a reference transistor.

The fourth transistor T4 may be electrically connected between the first transistor T1 and the initialization voltage line VL. The fourth transistor T4 may include a gate connected to the initialization gate line GIL, a first terminal connected to the sixth transistor T6 and the light emitting diode LEE, and a second terminal connected to the initialization voltage line VL. The fourth transistor T4 may be turned on by the initialization signal GI received through the initialization gate line GIL, to transmit the initialization voltage Vaint received through the initialization voltage line VL, to the pixel electrode of the light emitting diode LED. The fourth transistor T4 may also be referred to as an initialization transistor.

The fifth transistor T5 may be electrically connected between the driving voltage line PL and the first transistor T1. The fifth transistor T5 may include a gate connected to the first emission control line EML, a first terminal connected to the driving voltage line PL, and a second terminal connected to the first terminal of the first transistor T1. The fifth transistor T5 may be turned on or off according to the first emission control signal EM received through the first emission control line EML. The fifth transistor T5 may also be referred to as a driving control transistor.

The sixth transistor T6 may be connected between the first transistor T1 and the light emitting diode LED. The sixth transistor T6 may include a gate connected to the second emission control line EMBL, a first terminal connected to the second node N2, and a second terminal connected to the light emitting diode LED. The sixth transistor T6 may be turned on by the second emission control signal EMB received through the second emission control line EMBL, to connect the second node N2 and the pixel electrode of the light emitting diode LED to each other. The sixth transistor T6 may also be referred to as an emission control transistor.

Although FIG. 5 illustrates that the fifth transistor T5 and the sixth transistor T6 operate in response to different emission control signals EM and EMB, the disclosure is not necessarily limited thereto. In an embodiment, the fifth transistor T5 and the sixth transistor T6 may operate in response to the same emission control signal.

In an embodiment, the reference signal GR may be substantially synchronized with the scan signal GW of the pixel circuit PC located in the previous row. The initialization signal GI may be substantially synchronized with the scan signal GW. In an embodiment, the initialization signal GI may be substantially synchronized with the reference signal GR or the scan signal GW of the pixel circuit PC located in the next row.

The storage capacitor Cst may be connected between the first node N1 and the second node N2. For example, the pixel circuit PC, according to an embodiment of the disclosure, may be a source follower type circuit in which the storage capacitor Cst is connected between the first node N1 and the second node N2. A first storage electrode CEs1 of the storage capacitor Cst may be connected to the first node N1, and a second storage electrode CEs2 thereof may be connected to the second node N2. The storage capacitor Cst may store a threshold voltage of the first transistor T1 and a voltage corresponding to the data signal DATA.

In an embodiment, the hold capacitor Chd may be connected between the driving voltage line PL and the second node N2. A first hold electrode CEh1 of the hold capacitor Chd may be connected to the driving voltage line PL, and a second hold electrode CEh2 thereof may be connected to the second node N2. The hold capacitor Chd may allow the voltage of the second node N2 and the lower gate electrode of the first transistor T1 to have a constant voltage without fluctuation even when an ambient signal fluctuates.

The light emitting diode LED may include a pixel electrode connected to the second node N2 and an opposite electrode over the pixel electrode, and the opposite electrode may receive a common voltage ELVSS. The opposite electrode may be a common electrode shared by a plurality of light emitting diodes LED.

Although FIG. 5 illustrates that the pixel circuit PC includes six transistors and two capacitors, the disclosure is not necessarily limited thereto. In an embodiment, the pixel circuit PC may include five transistors and two capacitors. In an embodiment, the pixel circuit PC may include seven transistors and two capacitors.

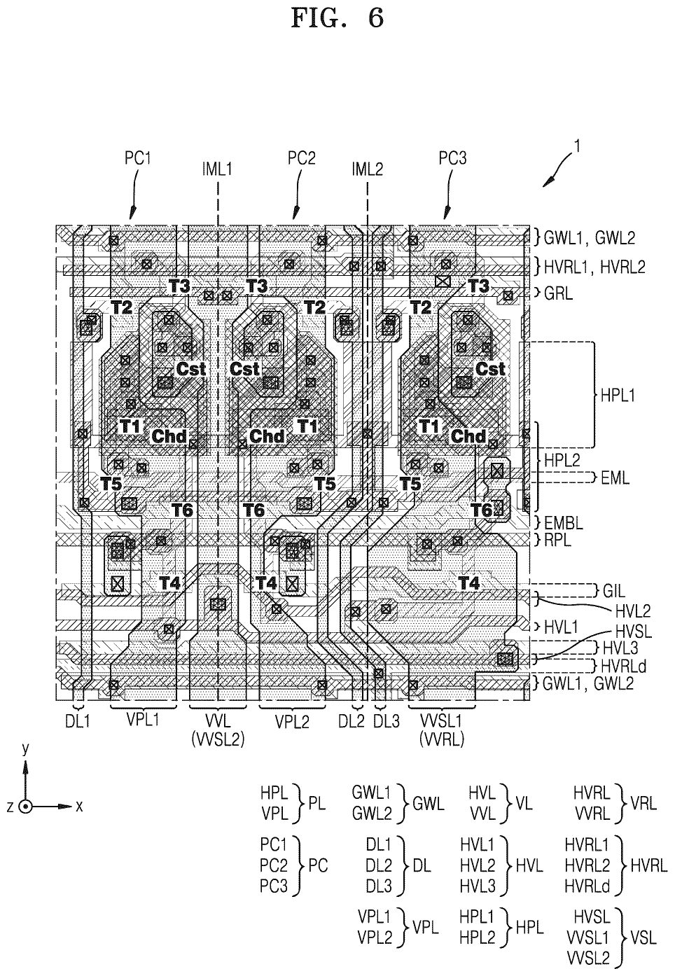

FIG. 6 is a plan view schematically illustrating pixel circuits of a display apparatus according to an embodiment of the disclosure. For convenience of description, FIG. 6 illustrates three pixel circuits, for example, a first pixel circuit PC1, a second pixel circuit PC2, and a third pixel circuit PC3, disposed in the same row in the first direction (e.g., x-axis direction); however, the disclosure is not necessarily limited thereto. A display apparatus 1 may include a plurality of pixel circuits that are disposed in rows in the first direction (e.g., x-axis direction) and in columns in the second direction (e.g., y-axis direction).

Referring to FIG. 6, each of the first pixel circuit PC1, the second pixel circuit PC2, and the third pixel circuit PC3 may include transistors and capacitors. In an embodiment, each of the first pixel circuit PC1, the second pixel circuit PC2, and the third pixel circuit PC3 may include the first to sixth transistors T1, T2, T3, T4, T5, and T6, the storage capacitor Cst, and the hold capacitor Chd described above with reference to FIG. 5.

Each of the first pixel circuit PC1, the second pixel circuit PC2, and the third pixel circuit PC3 may be electrically connected to a gate line configured to transmit a signal to the gate of each of the first to sixth transistors T1, T2, T3, T4, T5, and T6. For example, the pixel circuit PC may be connected to a scan line GWL configured to transmit a scan signal, an initialization gate line GIL configured to transmit an initialization signal, a reference gate line GRL configured to transmit a reference signal, a first emission control line EML configured to transmit a first emission control signal, a second emission control line EMBL configured to transmit a second emission control signal, a hold gate line GHL configured to transmit a hold signal, and a data line DL configured to transmit a data signal. Also, each of the first pixel circuit PC1, the second pixel circuit PC2, and the third pixel circuit PC3 may be connected to a driving voltage line PL configured to transmit a driving voltage, a reference voltage line VRL configured to transmit a reference voltage, and an initialization voltage line VL configured to transmit an initialization voltage.

Referring to FIG. 6, the transistors and capacitors of the first pixel circuit PC1 may be symmetrically disposed with respect to the transistors and capacitors of the second pixel circuit PC2, respectively. For example, the first transistor T1 of the first pixel circuit PC1 may be symmetrical to the first transistor T1 of the second pixel circuit PC2 with respect to an imaginary line IML1 passing between the first pixel circuit PC1 and the second pixel circuit PC2 in the second direction (e.g., y-axis direction). Similarly, the second to sixth transistors T2, T3, T4, T5, and T6, the storage capacitor Cst, and the hold capacitor Chd of the first pixel circuit PC1 may be symmetrical to the second to sixth transistors T2, T3, T4, T5, and T6, the storage capacitor Cst, and the hold capacitor Chd of the second pixel circuit PC2 with respect to the imaginary line IML1, respectively.

Likewise, the transistors and capacitors of the second pixel circuit PC2 may be symmetrically disposed with respect to the transistors and capacitors of the third pixel circuit PC3, respectively. For example, the first transistor T1 of the second pixel circuit PC2 may be symmetrical to the first transistor T1 of the third pixel circuit PC3 with respect to an imaginary line IML2 passing between the second pixel circuit PC2 and the third pixel circuit PC3 in the second direction (e.g., y-axis direction). Similarly, the second to sixth transistors T2, T3, T4, T5, and T6, the storage capacitor Cst, and the hold capacitor Chd of the second pixel circuit PC2 may be symmetrical to the second to sixth transistors T2, T3, T4, T5, and T6, the storage capacitor Cst, and the hold capacitor Chd of the third pixel circuit PC3 with respect to the imaginary line IML2, respectively.

The gate lines electrically connected to the first pixel circuit PC1, the second pixel circuit PC2, and the third pixel circuit PC3, for example, the scan line GWL, the initialization gate line GIL, the reference gate line GRL, the first emission control line EML, the second emission control line EMBL, and the hold gate line GHL, may extend in the first direction (e.g., x-axis direction).

The first pixel circuit PC1, the second pixel circuit PC2, and the third pixel circuit PC3 may be electrically connected to the data line DL passing through each pixel circuit PC. For example, the first pixel circuit PC1 may be electrically connected to a first data line DL1 passing through the first pixel circuit PC1, the second pixel circuit PC2 may be electrically connected to a second data line DL2 passing through the second pixel circuit PC2, and the third pixel circuit PC3 may be connected to a third data line DL3 passing through the third pixel circuit PC3. The data line DL may extend in the second direction (e.g., y-axis direction). With respect to the first direction (e.g., x-axis direction), the first data line DL1 may be disposed on the left side of the first transistor T1 in the first pixel circuit PC1, the second data line DL2 may be disposed on the right side of the first transistor T1 in the second pixel circuit PC2, and the third data line DL3 may be disposed on the left side of the first transistor T1 in the third pixel circuit PC3. For example, the first data line DL1 and the second data line DL2 may be disposed distantly with respect to the imaginary line IML1, and the second data line DL2 and the third data line DL3 may be disposed adjacently with respect to the imaginary straight line IML2.

The first pixel circuit PC1, the second pixel circuit PC2, and the third pixel circuit PC3 may be electrically connected to the voltage line passing through each pixel circuit PC. For example, each of the first pixel circuit PC1, the second pixel circuit PC2, and the third pixel circuit PC3 may be electrically connected to a reference voltage line VRL, an initialization voltage line VL, a driving voltage line PL, and a common voltage line VSL. The reference voltage line VRL may include a horizontal reference voltage line HVRL extending in the first direction (e.g., x-axis direction) and a vertical reference voltage line VVRL extending in the second direction (e.g., y-axis direction). The horizontal reference voltage line HVRL and the vertical reference voltage line VVRL may be electrically connected to each other in an intersection area thereof. In an embodiment, the vertical reference voltage line VVRL may be disposed on an area where the third pixel circuit PC3 is disposed. Moreover, in an embodiment, the vertical reference voltage line VVRL may also function as a first vertical common voltage line VVSL1 among vertical common voltage lines VVSL described below.

The initialization voltage line VL may include a horizontal initialization voltage line HVL extending in the first direction (e.g., x-axis direction) and a vertical initialization voltage line VVL extending in the second direction (e.g., y-axis direction). The horizontal initialization voltage line HVL and the vertical initialization voltage line VVL may be electrically connected to each other in an intersection area thereof. In an embodiment, the vertical initialization voltage line VVL may be disposed on the boundary between the first pixel circuit PC1 and the second pixel circuit PC2. For example, the vertical initialization voltage line VVL may be disposed on the imaginary line IML1 such that a portion of the vertical initialization voltage line VVL may be disposed on an area where the first pixel circuit PC1 is disposed and another portion of the vertical initialization voltage line VVL may be disposed on an area where the second pixel circuit PC2 is disposed. Moreover, in an embodiment, the vertical initialization voltage line VVL may also function as a second vertical common voltage line VVSL2 among the vertical common voltage lines VVSL described below.

The horizontal initialization voltage line HVL may include a plurality of lines. For example, the horizontal initialization voltage line HVL may include a first horizontal initialization voltage line HVL1 configured to transmit an initialization voltage to the first pixel circuit PC1, a second horizontal initialization voltage line HVL2 configured to transmit an initialization voltage to the second pixel circuit PC2, and a third horizontal initialization voltage line HVL3 configured to transmit an initialization voltage to the third pixel circuit PC3.

The driving voltage line PL may include a horizontal driving voltage line HPL extending in the first direction (e.g., x-axis direction) and a vertical driving voltage line VPL extending in the second direction (e.g., y-axis direction). The horizontal driving voltage line HPL and the vertical driving voltage line VPL may be electrically connected to each other in an intersection area thereof. In an embodiment, the vertical driving voltage line VPL may be disposed on each of an area where the first pixel circuit PC1 is disposed and an area where the second pixel circuit PC2 is disposed. For example, the vertical driving voltage line VPL may include a first vertical driving voltage line VPL1 disposed on the first pixel circuit PC1 and a second vertical driving voltage line VPL2 disposed on the second pixel circuit PC2. The first vertical driving voltage line VPL1 and the second vertical driving voltage line VPL2 may be symmetrical with respect to the imaginary line IML1.

The common voltage line VSL may include a horizontal common voltage line HVSL extending in the first direction (e.g., x-axis direction) and a vertical common voltage line VVSL extending in the second direction (e.g., x-axis direction). The horizontal common voltage line HVSL and the vertical common voltage line VVSL may be electrically connected to each other in an intersection area thereof. The horizontal common voltage line HVSL may extend in the first direction (e.g., x-axis direction) to pass through the first pixel circuit PC1, the second pixel circuit PC2, and the third pixel circuit PC3. The vertical common voltage line VVSL may include a second vertical common voltage line VVSL2 disposed on the third pixel circuit PC3 and a second vertical common voltage line VVSL2 disposed on the imaginary line IML1. As described above, in an embodiment, the first vertical common voltage line VVSL1 may also function as the vertical reference voltage line VVRL. In an embodiment, the second vertical common voltage line VVSL2 may also function as the vertical initialization voltage line VVL.

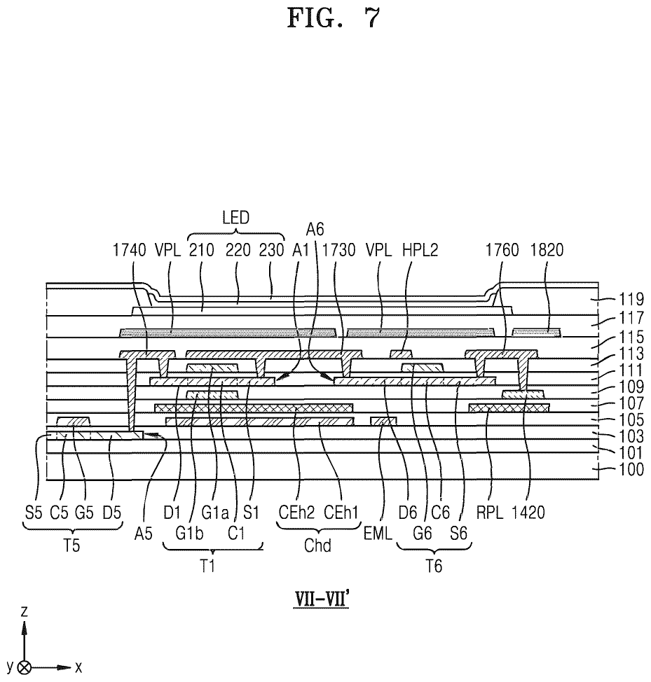

FIG. 7 is a schematic cross-sectional view of a display apparatus according to an embodiment of the disclosure and illustrates a cross-section taken along line VII-VII′ of FIG. 3.

Referring to FIG. 7, the display apparatus may include a circuit layer including transistors and capacitors disposed on a substrate 100, and a display element layer disposed on the circuit layer and including a light emitting diode LED. The circuit layer may include the transistors and capacitors described above with reference to FIG. 6, and for convenience of description, FIG. 7 illustrates only the first transistor T1, the fifth transistor T5, the sixth transistor T6, and the hold capacitor Chd.

The substrate 100 may include a glass material, a ceramic material, a metal material, plastic, or a flexible or bendable material. When the substrate 100 has flexible or bendable characteristics, the substrate 100 may include a polymer resin such as polyethersulfone (PES), polyacrylate, polyether imide (PEI), polyethylene naphthalate (PEN), polyethylene terephthalate (PET), polyphenylene sulfide (PPS), polyarylate, polyimide (PI), polycarbonate, and cellulose acetate propionate (CAP).

The substrate 100 may have a single-layer or multi-layer structure of the above material and may further include an inorganic layer in the case of having a multi-layer structure. For example, the substrate 100 may have a structure in which a layer including the above polymer resin and a barrier layer including an inorganic insulator are alternately stacked.

A buffer layer 101 may be disposed on the substrate 100. The buffer layer 101 may be an inorganic insulating layer including an inorganic insulating material such as silicon nitride and/or silicon oxide and may have a single-layer or multi-layer structure including the above material.

A transistor including a silicon semiconductor layer may be disposed on the buffer layer 101. In this regard, FIG. 7 illustrates a fifth semiconductor layer A5 of the fifth transistor T5. The first semiconductor layer A5 may include polysilicon. The fifth semiconductor layer A5 may include a channel area C5 and doped areas S5 and D5 disposed on both sides of the channel area C5. One of the doped areas S5 and D5 of the fifth semiconductor layer A5 may be a source and the other one may be a drain.

In some embodiments, a lower metal layer may be added between the buffer layer 101 and the silicon semiconductor layer. The lower metal layer may include one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The lower metal layer may have a voltage level of a constant voltage. For example, the lower metal layer may be electrically connected to the first power supply line 15 (see FIG. 3) outside the display area DA (see FIG. 3).

A first gate insulating layer 103 may be disposed on the fifth semiconductor layer A5. The first gate insulating layer 103 may include an inorganic insulating layer including an inorganic insulating material such as silicon oxide, silicon nitride, and/or silicon oxynitride and may have a single-layer or multi-layer structure including the above material.

A fifth gate electrode G5 may be disposed on the first gate insulating layer 103 and may overlap the channel area C5 of the fifth semiconductor layer A5. An emission control line EML and a first hold electrode CEh1 of the hold capacitor Chd may be disposed on the same layer as the fifth gate electrode G5, for example, over the first gate insulating layer 103. As described below, the fifth gate electrode G5 may be formed in a partial area of the emission control line EML.

The fifth gate electrode G5 and the first hold electrode CEh1 of the hold capacitor Chd may include the same material. The fifth gate electrode G5 and the first hold electrode CEh1 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material. In an embodiment, the fifth gate electrode G5 and the first hold electrode CEh1 of the hold capacitor Chd may include a single layer including molybdenum.

A second gate insulating layer 105 may be disposed on the fifth gate electrode G5 and the first hold electrode CEh1 of the hold capacitor Chd. The second gate insulating layer 105 may include an inorganic insulating layer including an inorganic insulating material such as silicon oxide, silicon nitride, and/or silicon oxynitride and may have a single-layer or multi-layer structure including the above material. In an embodiment, the second gate insulating layer 105 may include a different material than the first gate insulating layer 103. For example, the first gate insulating layer 103 may include silicon oxide, and the second gate insulating layer 105 may include silicon nitride.

A second hold electrode CEh2 of the hold capacitor Chd may be disposed on the second gate insulating layer 105. The second hold electrode CEh2 may overlap the first hold electrode CEh1 of the hold capacitor Chd. A repair line RPL may be disposed on the same layer as the second hold electrode CEh2, for example, over the second gate insulating layer 105.

The second hold electrode CEh2 of the hold capacitor Chd and the repair line RPL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material. In an embodiment, the second hold electrode CEh2 and the repair line RPL may include a single layer including molybdenum.

A third gate insulating layer 107 may be disposed on the second hold electrode CEh2 and the repair line RPL. The third gate insulating layer 107 may include an inorganic insulating layer including an inorganic insulating material such as silicon oxide, silicon nitride, and/or silicon oxynitride and may have a single-layer or multi-layer structure including the above material.

A first lower gate electrode G1b of the first transistor T1 and a fifth conductive pattern 1420 may be disposed on the third gate insulating layer 107. As described above, the first transistor T1 may have a dual-gate structure and may include a first upper gate electrode G1a and a first lower gate electrode G1b that overlap the channel area of the first transistor T1. As described below, the fifth conductive pattern 1420 may connect the repair line RPL and a 13th conductive pattern 1760 and may also be referred to as a repair bridge pattern.

The first lower gate electrode G1b and the fifth conductive pattern 1420 may include the same material. The first lower gate electrode G1b and the fifth conductive pattern 1420 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

A first interlayer insulating layer 109 may be disposed on the first lower gate electrode G1b and the fifth conductive pattern 1420. The first interlayer insulating layer 109 may include an inorganic insulating layer including an inorganic insulating material such as silicon oxide, silicon nitride, and/or silicon oxynitride and may have a single-layer or multi-layer structure including the above material. For example, the first interlayer insulating layer 109 may have a stack structure of a layer including silicon oxide and a layer including silicon nitride.

A first semiconductor layer A1 of the first transistor T1 and a sixth semiconductor layer A6 of the sixth transistor T6 may be disposed on the first interlayer insulating layer 109 and may include the same material. The first semiconductor layer A1 of the first transistor T1 and the sixth semiconductor layer A6 of the sixth transistor T6 may include an oxide semiconductor, and the oxide semiconductor may be an oxide semiconductor including at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the oxide semiconductor may include InSnZnO (ITZO) or InGaZnO (IGZO).

The first semiconductor layer A1 may include a channel area C1 and conductive areas S1 and D1 disposed on both sides of the channel area C1. One of the conductive areas S1 and D1 may be a source and the other one may be a drain. Likewise, the sixth semiconductor layer A6 may include a channel area C6 and conductive areas S6 and D6 disposed on both sides of the channel area C6. One of the conductive areas S6 and D6 may be a source and the other one may be a drain.

The first semiconductor layer A1 and the sixth semiconductor layer A6 may be disposed on a different layer than the fifth semiconductor layer A5 described above. For example, the vertical distance from the substrate 100 to the first semiconductor layer A1 may be greater than the vertical distance from the substrate 100 to the fifth semiconductor layer A5.

A fourth gate insulating layer 111 may be disposed on the first semiconductor layer A1 and the sixth semiconductor layer A6. The fourth gate insulating layer 111 may include an inorganic insulating layer including an inorganic insulating material such as silicon oxide, silicon nitride, and/or silicon oxynitride and may have a single-layer or multi-layer structure including the above material. In an embodiment, the fourth gate insulating layer 111 may include a single layer including silicon oxide.

FIG. 7 illustrates that the fourth gate insulating layer 111 passes through the side surface of the first semiconductor layer A1 and contacts the upper surface of the first interlayer insulating layer 109; however, the disclosure is not necessarily limited thereto. In an embodiment, the fourth gate insulating layer 111 may have substantially the same pattern and/or the same width as a first upper gate electrode G1a and a sixth gate electrode G6 described below. Alternatively, in an embodiment, the fourth gate insulating layer 111 may have a greater pattern and/or a greater width than the first upper gate electrode G1a described below and may have a smaller pattern and/or a smaller width than the first semiconductor layer A1. Likewise, the fourth gate insulating layer 111 may have a greater pattern and/or a greater width than a sixth gate electrode G6 described below and may have a smaller pattern and/or a smaller width than the sixth semiconductor layer A6. For example, the fourth gate insulating layer 111 might not contact the upper surface of the first interlayer insulating layer 109 beyond the side surface of the first semiconductor layer A1.

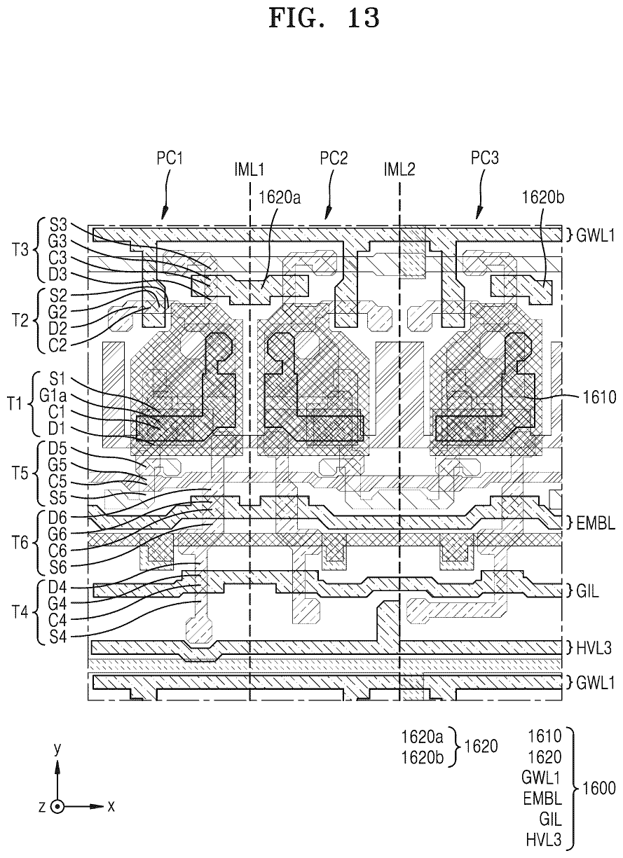

The first upper gate electrode G1a and the sixth gate electrode G6 may be disposed on the fourth gate insulating layer 111. The first upper gate electrode G1a may overlap the channel area C1 of the first semiconductor layer A1, and the sixth gate electrode G6 may overlap the channel area C6 of the sixth semiconductor layer A6. As described below, the sixth gate electrode G6 may be formed in a partial area of the second emission control line EMBL (see FIG. 13). The first upper gate electrode G1a and the sixth gate electrode C6 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material. In an embodiment, the first upper gate electrode G1a and the sixth gate electrode G6 may have a three-layer structure of titanium layer/aluminum layer/titanium layer.

A second interlayer insulating layer 113 may be disposed on the first upper gate electrode G1a and the sixth gate electrode G6. The second interlayer insulating layer 113 may include an inorganic insulating layer including an inorganic insulating material such as silicon oxide, silicon nitride, and/or silicon oxynitride and may have a single-layer or multi-layer structure including the above material. In an embodiment, the second interlayer insulating layer 113 may have a stack structure of a layer including silicon nitride and a layer including silicon oxynitride.

An 11th conductive pattern 1740, a 10th conductive pattern 1730, a second horizontal driving voltage line HPL2, and the 13th conductive pattern 1760 may be disposed on the same layer, for example, over the second interlayer insulating layer 113. The 11th conductive pattern 1740 may be a connection electrode connecting the fifth semiconductor layer A5 and the first semiconductor layer A1 to each other, and the 10th conductive pattern 1730 may be a connection electrode connecting the first semiconductor layer A1 and the sixth semiconductor layer A6 to each other. As described below, the 13th conductive pattern 1760 may connect the sixth semiconductor layer A6 and the light emitting diode LED through a 16th conductive pattern 1820. Thus, the 13th conductive pattern 1760 may also be referred to as a first pixel connection electrode.

The 11th conductive pattern 1740, the 10th conductive pattern 1730, the second horizontal driving voltage line HPL2, and the 13th conductive pattern 1760 may include the same material. The 11th conductive pattern 1740, the 10th conductive pattern 1730, the second horizontal driving voltage line HPL2, and the 13th conductive pattern 1760 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material. In an embodiment, the 11th conductive pattern 1740, the 10th conductive pattern 1730, the second horizontal driving voltage line HPL2, and the 13th conductive pattern 1760 may have a three-layer structure of titanium layer/aluminum layer/titanium layer.

A first organic insulating layer 115 may be disposed on the 11th conductive pattern 1740, the 10th conductive pattern 1730, the second horizontal driving voltage line HPL2, and the 13th conductive pattern 1760. The first organic insulating layer 115 may include an organic insulating material such as acryl, benzocyclobutene (BCB), polyimide, or hexamethyldisiloxane (HMDSO).

The vertical driving voltage line VPL and the 16th conductive pattern 1820 may be disposed on the first organic insulating layer 115. The 16th conductive pattern 1820 may connect the sixth semiconductor layer A6 and the light emitting diode LED through the 13th conductive pattern 1760. Thus, the 16th conductive pattern 1820 may also be referred to as a second pixel connection electrode. The vertical driving voltage line VPL and the 16th conductive pattern 1820 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material. In an embodiment, the vertical driving voltage line VPL and the 16th conductive pattern 1820 may have a three-layer structure of titanium layer/aluminum layer/titanium layer.

A second organic insulating layer 117 may be disposed on the vertical driving voltage line VPL and the 16th conductive pattern 1820. The second organic insulating layer 117 may include an organic insulating material such as acryl, benzocyclobutene (BCB), polyimide, or hexamethyldisiloxane (HMDSO).

The light emitting diode LED may be disposed on the second organic insulating layer 117. The light emitting diode LED may include a pixel electrode 210, an intermediate layer 220, and an opposite electrode 230 over the second organic insulating layer 117.

An outer portion of the pixel electrode 210 may be covered by a bank layer 119, and an inner portion of the pixel electrode 210 may overlap the intermediate layer 220 through an opening of the bank layer 119. The pixel electrode 210 may correspond to each light emitting diode LED, and the opposite electrode 230 may correspond to a plurality of light emitting diodes LED. For example, the opposite electrode 230 may overlap a plurality of pixel electrodes 210. The plurality of light emitting diodes LED may share the opposite electrode 230, and a stack structure of the pixel electrode 210, the intermediate layer 220, and the opposite electrode 230 may correspond to the light emitting diode LED.

The intermediate layer 220 may include an emission layer. In some embodiments, the intermediate layer 220 may further include an emission layer and a functional layer. The functional layer may include a hole transport layer (HTL), a hole injection layer (HIL), an electron transport layer (ETL), and/or an electron injection layer (EIL). In some embodiments, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. The light emission efficiency of the light emitting diode LED that is a tandem light emitting device including a plurality of emission layers may be further improved by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The opposite electrode 230 may include a conductive material having a low work function. The opposite electrode 230 may include a transparent or semitransparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer such as ITO, IZO, ZnO, or In₂O₃ over the transparent or semitransparent layer including the above material.

An encapsulation layer may be disposed on the light emitting diode LED. The encapsulation layer may include a first inorganic encapsulation layer, a second inorganic encapsulation layer, and an organic encapsulation layer interposed therebetween.

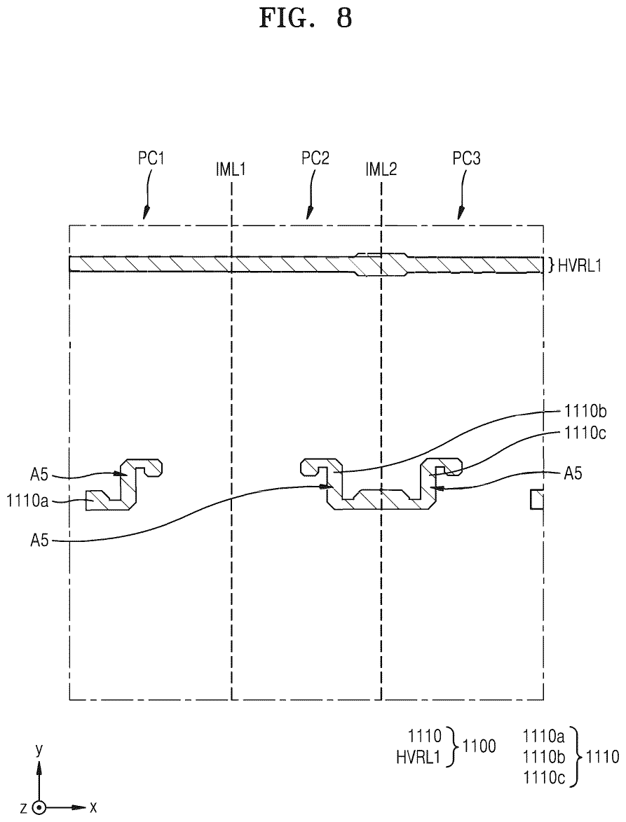

FIGS. 8 to 15 are plan views illustrating a process of forming a pixel circuit of a display apparatus according to an embodiment of the disclosure. FIGS. 8 to 15 illustrate a process of forming the components corresponding to the first pixel circuit PC1, the second pixel circuit PC2, and the third pixel circuit PC3 described above with reference to FIG. 6. For convenience of description, it is described that the first pixel circuit PC1 is located in the (i)th row and the (j)th column, the second pixel circuit PC2 is located in the (i)th row and the (j+1)th column, and the third pixel circuit PC3 is located in the (i)th row and the (j+2)th column.

Referring to FIG. 8, a silicon semiconductor layer 1100 may be disposed on a substrate. For example, the silicon semiconductor layer 1100 may include amorphous silicon or polysilicon. For example, the silicon semiconductor layer 1100 may include polysilicon crystallized at low temperature. The silicon semiconductor layer 1100 may include a first silicon semiconductor pattern 1110 and a first horizontal reference voltage line HVRL1 as illustrated in FIG. 8.

The first silicon semiconductor pattern 1110 may include a first-1 silicon semiconductor pattern 1110a disposed in the first pixel circuit PC1, a first-2 silicon semiconductor pattern 1110b disposed in the second pixel circuit PC2, and a first-3 silicon semiconductor pattern 1110c disposed in the third pixel circuit PC3. The first-1 silicon semiconductor pattern 1110a may have an isolated shape and may include a curved portion. The first-1 silicon semiconductor pattern 1110a may include a fifth semiconductor layer A5 of the first pixel circuit PC1. The first-2 silicon semiconductor pattern 1110b and the first-3 silicon semiconductor pattern 1110c may be connected to each other and formed as a united body. The first-2 silicon semiconductor pattern 1110b and the first-3 silicon semiconductor pattern 1110c may be symmetrical to each other with respect to the imaginary line IML2. The first-2 silicon semiconductor pattern 1110b may include a fifth semiconductor layer A5 of the second pixel circuit PC2, and the first-3 silicon semiconductor pattern 1110c may include a fifth semiconductor layer A5 of the third pixel circuit PC3. For example, the fifth semiconductor layer A5 of the second pixel circuit PC2 and the fifth semiconductor layer A5 of the third pixel circuit PC3 may be connected as a united body.

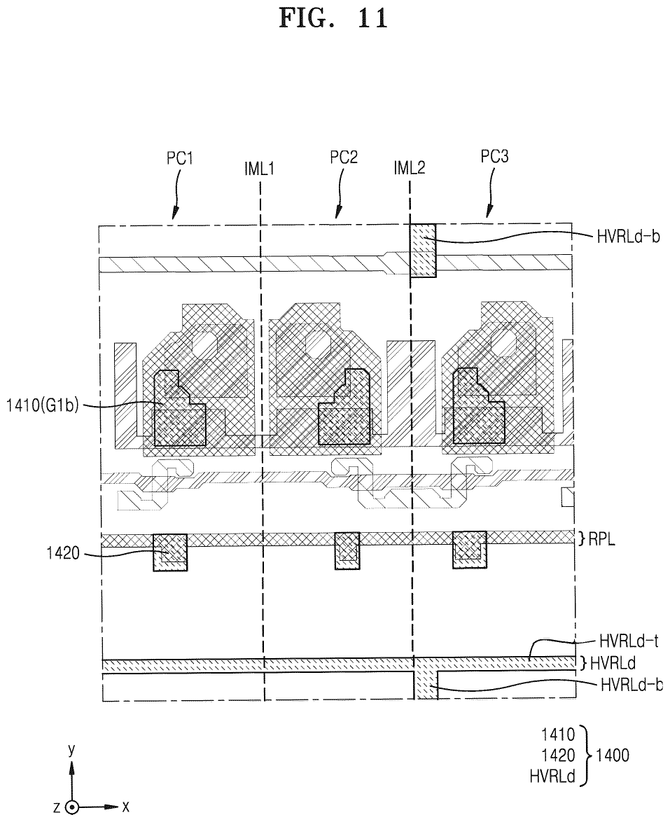

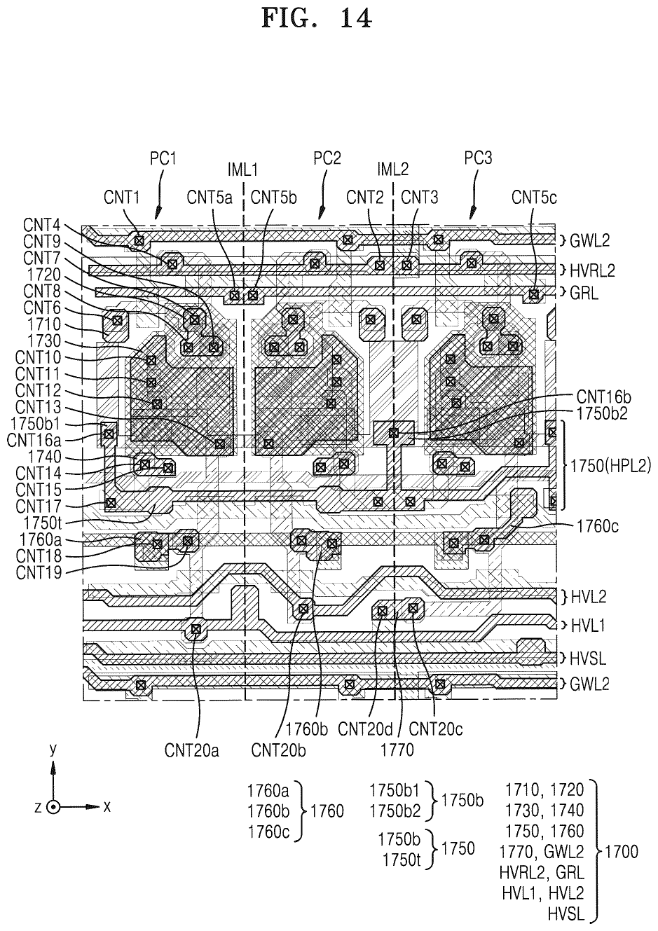

The first horizontal reference voltage line HVRL1 may extend in the first direction (e.g., x-axis direction) to pass through the first pixel circuit PC1, the second pixel circuit PC2, and the third pixel circuit PC3. The first horizontal reference voltage line HVRL1 may pass through the pixel circuits disposed in the same row as the first pixel circuit PC1, the second pixel circuit PC2, and the third pixel circuit PC3. The first horizontal reference voltage line HVRL1 may be electrically connected to a second horizontal reference voltage line HVRL2 (see FIG. 14) and a dummy horizontal reference voltage line HVRLd (see FIG. 11) to transmit a reference voltage to each pixel circuit. The first horizontal reference voltage line HVRL1 may overlap the second horizontal reference voltage line HVRL2 (see FIG. 14) in the plan view.

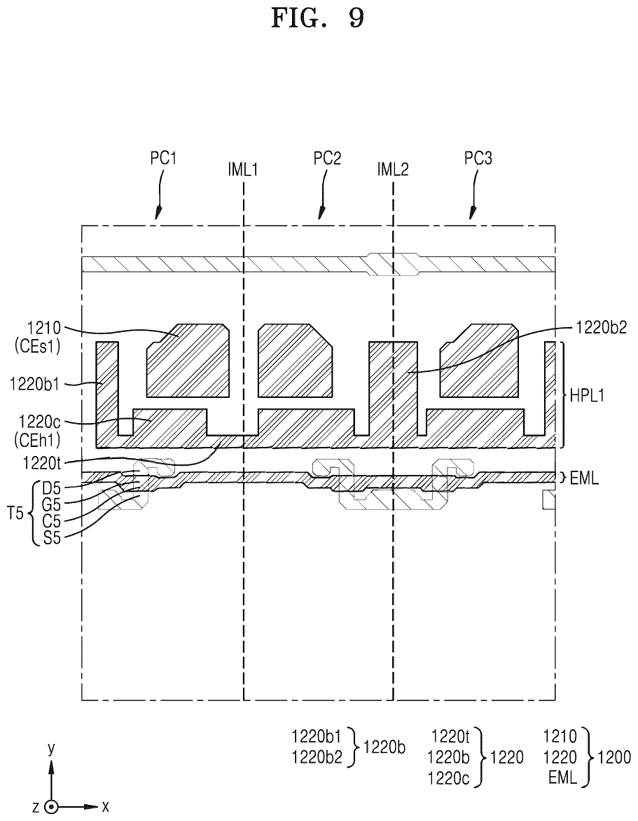

Referring to FIG. 9, a first conductive layer 1200 may be disposed on the silicon semiconductor layer 1100. The first conductive pattern 1200 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The first conductive layer 1200 may include a first emission control line EML, a first conductive pattern 1210, and a second conductive pattern 1220. The first emission control line EML, the first conductive pattern 1210, and the second conductive pattern 1220 may be spaced apart from each other.

The first emission control line EML may extend in the first direction (e.g., x-axis direction) to pass through the first pixel circuit PC1, the second pixel circuit PC2, and the third pixel circuit PC3. The first emission control line EML may pass through the pixel circuits disposed in the same row as the first pixel circuit PC1, the second pixel circuit PC2, and the third pixel circuit PC3.

The first emission control line EML may include the fifth gate electrode G5 of the fifth transistor T5 of each of the first pixel circuit PC1, the second pixel circuit PC2, and the third pixel circuit PC3. An area of the first emission control lines EML overlapping the first silicon semiconductor pattern 1110 (see FIG. 8) may correspond to the fifth gate electrode G5 of the fifth transistor T5. The fifth semiconductor layer A5 (see FIG. 8) of the fifth transistor T5 may include a channel area C5 overlapping the fifth gate electrode G5, and doped areas S5 and D5 respectively disposed on both sides of the channel area C5. One of the doped areas S5 and D5 may be a source area and the other one may be a drain area. The source area and the drain area may respectively correspond to a source electrode and a drain electrode. The positions of the source area and the drain area may be interchanged with each other depending on the properties of the transistor.

The first conductive pattern 1210 may be disposed in each of the first pixel circuit PC1, the second pixel circuit PC2, and the third pixel circuit PC3. The first conductive pattern 1210 may have an isolated shape. The first conductive pattern 1210 of the first pixel circuit PC1 may be symmetrically disposed with respect to the first conductive pattern 1210 of the second pixel circuit PC2 with respect to the imaginary line IML1. Likewise, the first conductive pattern 1210 of the second pixel circuit PC2 and the first conductive pattern 1210 of the third pixel circuit PC3 may be symmetrically disposed with respect to the imaginary line IML2. The first conductive pattern 1210 may include the first storage electrode CEs1 of the storage capacitor Cst (see FIG. 6) described above with reference to FIG. 6.

The second conductive pattern 1220 may extend in the first direction (e.g., x-axis direction) to pass through the first pixel circuit PC1, the second pixel circuit PC2, and the third pixel circuit PC3. For example, the second conductive pattern 1220 may include a stem portion 1220t extending in the first direction (e.g., x-axis direction), a branch portion 1220b branching from the stem portion 1220t and extending in the second direction (e.g., y-axis direction), and a capacitor portion 1220c extending from the stem portion 1220t and having a rectangular shape.

The capacitor portion 1220c of the second conductive pattern 1220 may be disposed in each of the first pixel circuit PC1, the second pixel circuit PC2, and the third pixel circuit PC3. The capacitor portion 1220c of the second conductive pattern 1220 may include the first hold electrode CEh1 of the hold capacitor Chd (see FIG. 6) described above with reference to FIG. 6.

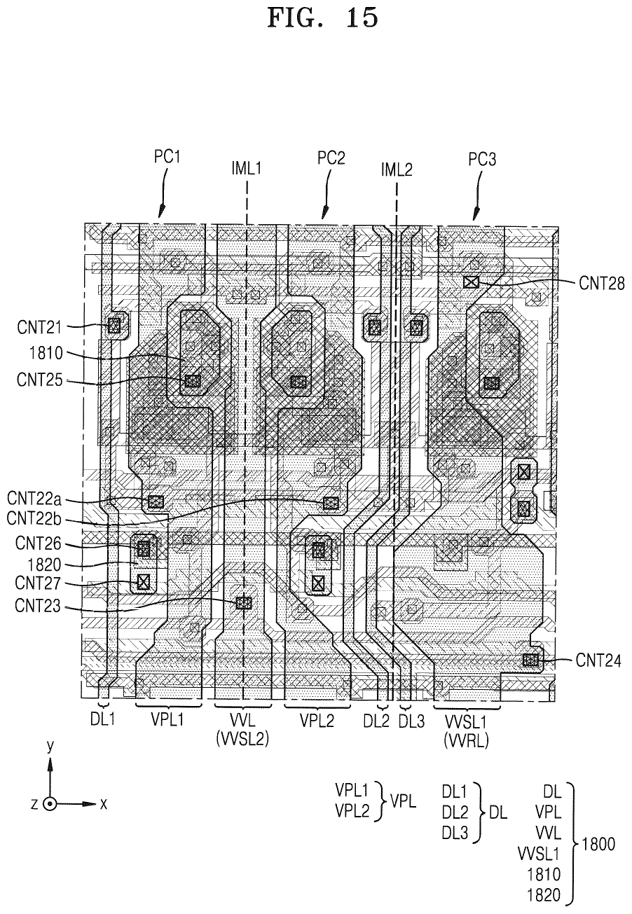

The branch portion 1220b of the second conductive pattern 1220 may include a first branch portion 1220b1 and a second branch portion 1220b2. The first branch portion 1220b1 may refer to a partial area of the second conductive pattern 1220 that branches from the end of the stem portion 1220t and extends in the second direction (e.g., y-axis direction). The second branch portion 1220b2 may refer to a partial area of the second conductive pattern 1220 that is disposed between the capacitor portion 1220c of the second pixel circuit PC2 and the capacitor portion 1220c of the third pixel circuit PC3 and branches from the stem portion 1220t and extends in the second direction (e.g., y-axis direction). The branch portion 1220b of the second conductive pattern 1220 may be electrically connected to the second horizontal driving voltage line HPL2 (see FIG. 14) and the vertical driving voltage line VPL (see FIG. 15) to transmit a driving voltage to the capacitor portion 1220c. Thus, the second conductive pattern 1220 may also be referred to as a first horizontal driving voltage line HPL1.

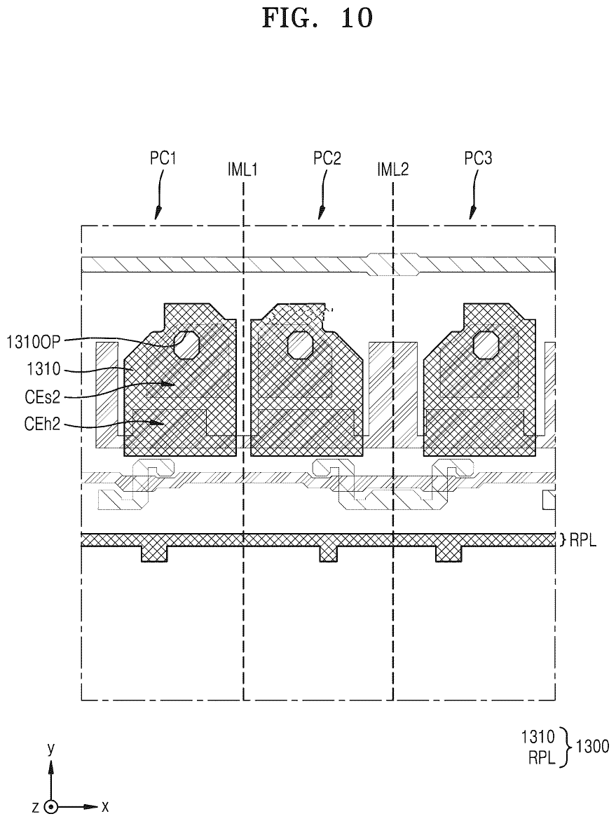

Referring to FIG. 10, a second conductive layer 1300 may be disposed on the first conductive layer 1200. The second conductive layer 1300 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The second conductive layer 1300 may include a repair line RPL and a third conductive pattern 1310. The repair line RPL and the third conductive pattern 1310 may be spaced apart from each other.

The repair line RPL may extend in the first direction (e.g., x-axis direction) to pass through the first pixel circuit PC1, the second pixel circuit PC2, and the third pixel circuit PC3. The repair line RPL may pass through the pixel circuits disposed in the same row as the first pixel circuit PC1, the second pixel circuit PC2, and the third pixel circuit PC3. As described above, when the pixel circuit is defective, the light emitting diode LED may be separated from the defective pixel circuit and the light emitting diode LED may be connected to the dummy circuit through the repair line RPL. As the dummy circuit generates a driving current corresponding to a data signal and supplies the driving current to the light emitting diode LED through the repair line, the light emitting diode LED may operate normally.

Accordingly, the repair line RPL may overlap the 13th conductive pattern 1760 (see FIG. 14) and the 16th conductive pattern 1820 (see FIG. 15) that are connected to the light emitting diode LED and are referred to as a pixel connection electrode. Also, the repair line RPL may overlap the fifth conductive pattern 1420 (see FIG. 11) that may act as an intermediate bridge between the 13th conductive pattern 1760 (see FIG. 14) and the repair line RPL, for example, a repair bridge pattern. The light emitting diode LED may be insulated from the repair line RPL, but may be electrically connected to the repair line RPL in a later repair process.

However, the repair line RPL is not necessarily limited to being disposed on the second conductive layer 1300. In some embodiments, the repair line RPL may be disposed on the first conductive layer 1200 (see FIG. 9). For example, the repair line RPL may be disposed on the same layer as the first conductive pattern 1210 (see FIG. 9), the second conductive pattern 1220 (see FIG. 9), and the emission control line EML (see FIG. 9).

The third conductive pattern 1310 disposed in each of the first pixel circuit PC1, the second pixel circuit PC2, and the third pixel circuit PC3 may have an isolated shape. The third conductive pattern 1310 disposed in the first pixel circuit PC1 and the third conductive pattern 1310 disposed in the second pixel circuit PC2 may be spaced apart from each other and may be substantially symmetrically disposed with respect to the imaginary line IML1 described above. The third conductive pattern 1310 disposed in the second pixel circuit PC2 and the third conductive pattern 1310 disposed in the third pixel circuit PC3 may be spaced apart from each other and may be substantially symmetrically disposed with respect to the imaginary line IML2 described above.

The third conductive pattern 1310 may overlap each of the first conductive pattern 1210 (see FIG. 9) and the second conductive pattern 1220 (see FIG. 9) of the first conductive layer 1200 (see FIG. 9). The third conductive pattern 1310 may include the second storage electrode CEs2 of the storage capacitor Cst (see FIG. 6) and the second hold electrode CEh2 of the hold capacitor Chd (see FIG. 6). An area of the third conductive patterns 1310 overlapping the first conductive pattern 1210 (see FIG. 9) that is the first storage electrode CEs1 (see FIG. 9) may be the second storage electrode CEs2 of the storage capacitor Cst (see FIG. 6). An area of the third conductive patterns 1310 overlapping the second conductive pattern 1220 (see FIG. 9) that is the first hold electrode CEh1 (see FIG. 9) may be the second hold electrode CEh2 of the hold capacitor Chd (see FIG. 6). For example, the second storage electrode CEs2 of the storage capacitor Cst (see FIG. 6) and the second hold electrode CEh2 of the hold capacitor Chd (see FIG. 6) may be formed as a united body. Moreover, the third conductive pattern 1310 may have a closed opening 1310OP in an area overlapping the first conductive pattern 1210 (see FIG. 9).

Referring to FIG. 11, a third conductive layer 1400 may be disposed on the second conductive layer 1300. The third conductive layer 1400 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The third conductive layer 1400 may include a fourth conductive pattern 1410, a fifth conductive pattern 1420, and a dummy horizontal reference voltage line HVRLd. The fourth conductive pattern 1410, the fifth conductive pattern 1420, and the dummy horizontal reference voltage line HVRLd may be spaced apart from each other.

The fourth conductive pattern 1410 may be disposed in each of the first pixel circuit PC1, the second pixel circuit PC2, and the third pixel circuit PC3. The fourth conductive pattern 1410 may have an isolated shape. The fourth conductive pattern 1410 of the first pixel circuit PC1 may be symmetrically disposed with respect to the fourth conductive pattern 1410 of the second pixel circuit PC2 with respect to the imaginary line IML1, and the fourth conductive pattern 1410 of the second pixel circuit PC2 and the fourth conductive pattern 1410 of the third pixel circuit PC3 may be symmetrically disposed with respect to the imaginary line IML2. The fourth conductive pattern 1410 may overlap the third conductive pattern 1310 (see FIG. 10). The fourth conductive pattern 1410 may include the first lower gate electrode G1b of the first transistor T1 (see FIG. 6) and may be electrically connected to the 10th conductive pattern 1730 (see FIG. 14) described below.

The fifth conductive pattern 1420 may be disposed in each of the first pixel circuit PC1, the second pixel circuit PC2, and the third pixel circuit PC3. The fifth conductive pattern 1420 may have an isolated square shape. The fifth conductive pattern 1420 of the first pixel circuit PC1 may be symmetrically disposed with respect to the fifth conductive pattern 1420 of the second pixel circuit PC2 with respect to the imaginary line IML1, and the fifth conductive pattern 1420 of the second pixel circuit PC2 and the fifth conductive pattern 1420 of the third pixel circuit PC3 may be symmetrically disposed with respect to the imaginary line IML2.

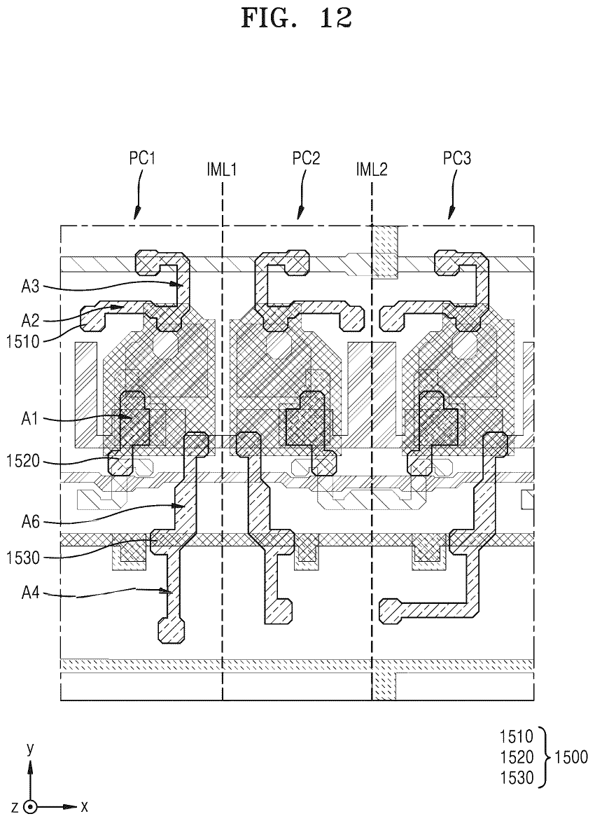

The fifth conductive pattern 1420 may partially overlap the repair line RPL and may partially overlap the 13th conductive pattern 1760 (see FIG. 14) and the 16th conductive pattern 1820 (see FIG. 15) described below. The 13th conductive pattern 1760 (see FIG. 14) and the 16th conductive pattern 1820 (see FIG. 15) may be a pixel connection electrode connecting a third oxide semiconductor pattern 1530 (see FIG. 12) and the light emitting diode LED (see FIG. 9). When the pixel circuit is defective, in a repair process, the third oxide semiconductor pattern 1530 (see FIG. 12) and the pixel connection electrode may be insulated from each other and the pixel connection electrode and the repair line RPL may be electrically connected to each other. In this case, the fifth conductive pattern 1420 may be disposed between the repair line RPL and the 13th conductive pattern 1760 (see FIG. 14), which is the pixel connection electrode, and may function as an intermediate bridge between the repair line RPL and the 13th conductive pattern 1760 (see FIG. 14). For example, the fifth conductive pattern 1420 may be referred to as a repair bridge pattern.

As the fifth conductive pattern 1420 is disposed between the repair line RPL and the 13th conductive pattern 1760 (see FIG. 14), the thickness of the insulating layers disposed between the repair line RPL and the 13th conductive pattern 1760 (see FIG. 14) may be reduced. In the repair process, the success rate of the repair process may decrease as the thickness of the insulating layer between two conductive patterns that should be shorted increases. Accordingly, in the display apparatus according to an embodiment of the disclosure, the repair bridge pattern may be disposed between the repair line RPL and the pixel connection electrode to reduce the thickness of the insulating layer between the repair line RPL and the pixel connection electrode and efficiently improve the repair success rate.

The dummy horizontal reference voltage line HVRLd may extend in the first direction (e.g., x-axis direction) to pass through the first pixel circuit PC1, the second pixel circuit PC2, and the third pixel circuit PC3. The dummy horizontal reference voltage line HVRLd may pass through the pixel circuits disposed in the same row as the first pixel circuit PC1, the second pixel circuit PC2, and the third pixel circuit PC3. The dummy horizontal reference voltage line HVRLd may be electrically connected to the first horizontal reference voltage line HVRL1 (see FIG. 8) and the second horizontal reference voltage line HVRL2 (see FIG. 14) to transmit a reference voltage to each pixel circuit.

For example, the dummy horizontal reference voltage line HVRLd may include a stem portion HVRLd-t extending in the first direction (e.g., x-axis direction) and a branch portion HVRLd-b branching from the stem portion HVRLd-t and extending in the second direction (e.g., y-axis direction). The branch portion HVRLd-b of the dummy horizontal reference voltage line HVRLd may overlap the first horizontal reference voltage line HVRL1 (see FIG. 8) and the second horizontal reference voltage line HVRL2 (see FIG. 14). As described below, the branch portion HVRLd-b of the dummy horizontal reference voltage line HVRLd may be connected to the second horizontal reference voltage line HVRL2 (see FIG. 14) through a contact hole in an area overlapping the second horizontal reference voltage line HVRL2 (see FIG. 14).

Like the dummy horizontal reference voltage line HVRLd, the third conductive layer 1400 may include a dummy line electrically connected to at least one of the plurality of voltage lines. As described above, the third conductive layer 1400 may include a fourth conductive pattern 1410 and a fifth conductive pattern 1420. However, because the planar area of the fourth conductive pattern 1410 and the fifth conductive pattern 1420 are not large, the pattern density of the third conductive layer 1400 may be relatively small compared to other conductive layers or semiconductor layers. Each of the conductive layer and the semiconductor layer may include a pattern formed through a deposition process, a photolithography process, an etching process, and the like. In this case, when the pattern density of a particular layer is low, the pattern may be nonuniformly deposited or a process problem such as an exposure failure, overetching, or underetching may occur.

Accordingly, in the display apparatus, according to an embodiment of the disclosure, a dummy line may be additionally disposed in the third conductive layer 1400 having a relatively low pattern density to increase the pattern density of the third conductive layer 1400 and improve the stability of the display apparatus manufacturing process. In addition, by electrically connecting the dummy line to one of the plurality of voltage lines connected to the pixel circuit, the voltage line may be designed more flexibly and the resistance of the voltage line and the power consumption of the display apparatus may be efficiently reduced.

Referring to FIG. 12, an oxide semiconductor layer 1500 may be disposed on the third conductive layer 1400. For example, the oxide semiconductor layer 1500 may include an oxide semiconductor, and the oxide semiconductor may include at least one of indium (In), gallium (Ga), stannium (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the oxide semiconductor layer 1500 may include InSnZnO (ITZO) or InGaZnO (IGZO).

The oxide semiconductor layer 1500 may include a first oxide semiconductor pattern 1510, a second oxide semiconductor pattern 1520, and a third oxide semiconductor pattern 1530. The first oxide semiconductor pattern 1510, the second oxide semiconductor pattern 1520, and the third oxide semiconductor pattern 1530 may be spaced apart from each other.

The first oxide semiconductor pattern 1510 disposed in each of the first pixel circuit PC1, the second pixel circuit PC2, and the third pixel circuit PC3 may have an isolated shape. The first oxide semiconductor pattern 1510 may be bent to have a substantially “L” shape. The first oxide semiconductor pattern 1510 of the first pixel circuit PC1 and the first oxide semiconductor pattern 1510 of the second pixel circuit PC2 may be symmetrically disposed with respect to the imaginary line IML1, and the first oxide semiconductor pattern 1510 of the second pixel circuit PC2 and the first oxide semiconductor pattern 1510 of the third pixel circuit PC3 may be symmetrically disposed with respect to the imaginary line IML2.

The first oxide semiconductor pattern 1510 may include a second semiconductor layer A2 of the second transistor T2 (see FIG. 6) and a third semiconductor layer A3 of the third transistor T3 (see FIG. 6). For example, the second semiconductor layer A2 of the second transistor T2 (see FIG. 6) and the third semiconductor layer A3 of the third transistor T3 (see FIG. 6) may be connected as a united body. The second semiconductor layer A2 may overlap a first scan line GWL1 (see FIG. 13) described below, and the third semiconductor layer A3 may overlap a seventh conductive pattern 1620 (see FIG. 13) described below.

The second oxide semiconductor pattern 1520 disposed in each of the first pixel circuit PC1, the second pixel circuit PC2, and the third pixel circuit PC3 may have an isolated shape. The second oxide semiconductor pattern 1520 may have a shape extending in the second direction (e.g., y-axis direction). The second oxide semiconductor pattern 1520 of the first pixel circuit PC1 and the second oxide semiconductor pattern 1520 of the second pixel circuit PC2 may be symmetrically disposed with respect to the imaginary line IML1, and the second oxide semiconductor pattern 1520 of the second pixel circuit PC2 and the second oxide semiconductor pattern 1520 of the third pixel circuit PC3 may be symmetrically disposed with respect to the imaginary line IML2.

The second oxide semiconductor pattern 1520 may include the first semiconductor layer A1 of the first transistor T1 (see FIG. 6). The first semiconductor layer A1 may overlap the fourth conductive pattern 1410 (see FIG. 11) and a sixth conductive pattern 1610 (see FIG. 13) described below. The fourth conductive pattern 1410 (see FIG. 11) and the sixth conductive pattern 1610 (see FIG. 13) may form a dual-gate structure of the first transistor T1 (see FIG. 6).

The third oxide semiconductor pattern 1530 disposed in each of the first pixel circuit PC1, the second pixel circuit PC2, and the third pixel circuit PC3 may have an isolated shape. The third oxide semiconductor pattern 1530 may have a shape extending in the second direction (e.g., y-axis direction). The third oxide semiconductor pattern 1530 of the first pixel circuit PC1 and the third oxide semiconductor pattern 1530 of the second pixel circuit PC2 may be symmetrically disposed with respect to the imaginary line IML1. However, the third oxide semiconductor pattern 1530 of the third pixel circuit PC3 may have an inverted ‘L’ shape by further including a partial area extending in the first direction (e.g., x-axis direction) compared to the third oxide semiconductor pattern 1530 of the first pixel circuit PC1.

The third oxide semiconductor pattern 1530 may include a fourth semiconductor layer A4 and a sixth semiconductor layer A6. For example, the fourth semiconductor layer A4 and the sixth semiconductor layer A6 may be integrally connected to each other. The sixth semiconductor layer A6 of the third oxide semiconductor pattern 1530 may overlap the second emission control line EMBL (see FIG. 13) described below, and the fourth semiconductor layer A4 of the third oxide semiconductor pattern 1530 may overlap the initialization gate line GIL (see FIG. 13) described below.

One end of the third oxide semiconductor pattern 1530 may be connected to the 10th conductive pattern 1730 (see FIG. 14) described below and may be electrically connected to the first transistor T1 (see FIG. 6). The other end of the third oxide semiconductor pattern 1530 may overlap and may be connected to the horizontal initialization voltage line HVL (see FIG. 6). For example, the third oxide semiconductor pattern 1530 of the first pixel circuit PC1 may be electrically connected to the first horizontal initialization voltage line HVL1 (see FIG. 14), and the third oxide semiconductor pattern 1530 of the second pixel circuit PC2 may be electrically connected to the second horizontal initialization voltage line HVL2 (see FIG. 14). The third oxide semiconductor pattern 1530 of the third pixel circuit PC3 may be electrically connected to the third horizontal initialization voltage line HVL3 (see FIG. 13) through a 14th conductive pattern 1770 (see FIG. 14).

Each of the first oxide semiconductor pattern 1510, the second oxide semiconductor pattern 1520, the third oxide semiconductor pattern 1530, and a fourth oxide semiconductor pattern 1540 may include at least a partially conductive area. For example, a conductorization process using plasma or the like may be performed on at least a portion of each of the first oxide semiconductor pattern 1510, the second oxide semiconductor pattern 1520, the third oxide semiconductor pattern 1530, and the fourth oxide semiconductor pattern 1540.

Referring to FIG. 13, a fourth conductive layer 1600 may be disposed on the oxide semiconductor layer 1500. The fourth conductive layer 1600 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The fourth conductive layer 1600 may include a first scan line GWL1, a second emission control line EMBL, an initialization gate line GIL, a third horizontal initialization voltage line HVL3, a sixth conductive pattern 1610, and a seventh conductive pattern 1620. The first scan line GWL1, the second emission control line EMBL, the initialization gate line GIL, the third horizontal initialization voltage line HVL3, the sixth conductive pattern 1610, and the seventh conductive pattern 1620 may be spaced apart from each other.

The first scan line GWL1 may extend in the first direction (e.g., x-axis direction) to pass through the first pixel circuit PC1, the second pixel circuit PC2, and the third pixel circuit PC3. The first scan line GWL1 may pass through the pixel circuits disposed in the same row as the first pixel circuit PC1 and the second pixel circuit PC2. The first scan line GWL1 may overlap a second scan line GWL2 (see FIG. 14) described below and may be electrically connected to the second scan line GWL2 (see FIG. 14).

The first scan line GWL1 may include a stem portion extending in the first direction (e.g., x-axis direction) and a branch portion protruding from the stem portion in the second direction (e.g., y-axis direction). The branch portion of the first scan line GWL1 may include an area overlapping the first oxide semiconductor pattern 1510 (see FIG. 12), for example, a second gate electrode G2 of the second transistor T2. Referring to FIGS. 12 and 13, the second semiconductor layer A2 of the second transistor T2 may include a channel area C2 overlapping the first scan line GWL1 and conductive areas S2 and D2 disposed on both sides of the channel area C2. One of the conductive areas S2 and D2 may be a source area, and the other one may be a drain area. The source area and the drain area may respectively correspond to a source electrode and a drain electrode. The positions of the source area and the drain area may be interchanged with each other depending on the properties of the transistor.

The second emission control line EMBL may extend in the first direction (e.g., x-axis direction) to pass through the first pixel circuit PC1, the second pixel circuit PC2, and the third pixel circuit PC3. The second emission control line EMBL may pass through the pixel circuits disposed in the same row as the first pixel circuit PC1 and the second pixel circuit PC2.

The second emission control line EMBL may include an area overlapping the third oxide semiconductor pattern 153 (see FIG. 12), for example, the sixth gate electrode G6 of the sixth transistor T6. Referring to FIGS. 12 and 13, the sixth semiconductor layer A6 of the sixth transistor T6 may include a channel area C6 overlapping the second emission control line EMBL and conductive areas S6 and D6 disposed on both sides of the channel area C6. One of the conductive areas S6 and D6 may be a source area, and the other one may be a drain area. The source area and the drain area may respectively correspond to a source electrode and a drain electrode. The positions of the source area and the drain area may be interchanged with each other depending on the properties of the transistor.

The initialization gate line GIL may extend in the first direction (e.g., x-axis direction) to pass through the first pixel circuit PC1, the second pixel circuit PC2, and the third pixel circuit PC3. The initialization gate line GIL may pass through the pixel circuits disposed in the same row as the first pixel circuit PC1 and the second pixel circuit PC2.

The initialization gate line GIL may include an area overlapping the third oxide semiconductor pattern 1530 (see FIG. 12), for example, a fourth gate electrode G4 of the fourth transistor T4. Referring to FIGS. 12 and 13, the fourth semiconductor layer A4 of the fourth transistor T4 may include a channel area C4 overlapping the initialization gate line GIL and conductive areas S4 and D4 disposed on both sides of the channel area C4. One of the conductive areas S4 and D4 may be a source area, and the other one may be a drain area. The source area and the drain area may respectively correspond to a source electrode and a drain electrode. The positions of the source area and the drain area may be interchanged with each other depending on the properties of the transistor.

The third horizontal initialization voltage line HVL3 may extend in the first direction (e.g., x-axis direction) to pass through the first pixel circuit PC1, the second pixel circuit PC2, and the third pixel circuit PC3. The third horizontal initialization voltage line HVL3 may pass through the pixel circuits disposed in the same row as the first pixel circuit PC1 and the second pixel circuit PC2. For example, the third horizontal initialization voltage line HVL3 may include a stem portion extending in the first direction (e.g., x-axis direction) and a branch portion branching from the stem portion and extending in the second direction (e.g., y-axis direction). The branch portion of the third horizontal initialization voltage line HVL3 may be connected to the third oxide semiconductor pattern 1530 (see FIG. 12) of the third pixel circuit PC3 through the 14th conductive pattern 1770 (see FIG. 14) described below.

The sixth conductive pattern 1610 disposed in each of the first pixel circuit PC1, the second pixel circuit PC2, and the third pixel circuit PC3 may have an isolated shape. The sixth conductive pattern 1610 of the first pixel circuit PC1 may be symmetrically disposed with respect to the sixth conductive pattern 1610 of the second pixel circuit PC2 with respect to the imaginary line IML1, and the sixth conductive pattern 1610 of the second pixel circuit PC2 may be symmetrically disposed with respect to the sixth conductive pattern 1610 of the third pixel circuit PC3 with respect to the imaginary line IML2.

The sixth conductive pattern 1610 disposed in each of the first pixel circuit PC1, the second pixel circuit PC2, and the third pixel circuit PC3 may have an “L” shape. One end of the sixth conductive pattern 1610 may be electrically connected to the first oxide semiconductor pattern 1510 (see FIG. 12) through a ninth conductive pattern 1720 (see FIG. 14). The other end of the sixth conductive pattern 1610 may include the first upper gate electrode G1a of the first transistor T1. Referring to FIGS. 12 and 13, the first semiconductor layer A1 of the first transistor T1 may include a channel area C1 overlapping the sixth conductive pattern 1610 and conductive areas S1 and D1 disposed on both sides of the channel area C1. One of the conductive areas S1 and D1 may be a source area, and the other one may be a drain area. The source area and the drain area may respectively correspond to a source electrode and a drain electrode. The positions of the source area and the drain area may be interchanged with each other depending on the properties of the transistor. In this case, a portion of the fourth conductive pattern 1410 (see FIG. 11) and the first upper gate electrode G1a may overlap each other with the channel area C1 interposed therebetween. A portion of the fourth conductive pattern 1410 (see FIG. 11) overlapping the channel area C1 of the first transistor T1 may correspond to the first lower gate electrode G1b (see FIG. 11) of the first transistor T1.

The seventh conductive pattern 1620 may have an isolated shape and may have a shape extending in the first direction (e.g., x-axis direction). For example, the seventh conductive pattern 1620 may include a seventh-1 conductive pattern 1620a disposed across the first pixel circuit PC1 and the second pixel circuit PC2 and a seventh-2 conductive pattern 1620b disposed in the third pixel circuit PC3. The seventh-1 conductive pattern 1620a may intersect the imaginary line IML1. For example, the seventh conductive pattern 1620 disposed in the first pixel circuit PC1 and the seventh conductive pattern 1620 disposed in the second pixel circuit PC2 may be integrally formed with each other.

The seventh conductive pattern 1620 of each of the first pixel circuit PC1, the second pixel circuit PC2, and the third pixel circuit PC3 may include a third gate electrode G3 of the third transistor T3. Referring to FIGS. 12 and 13, the third semiconductor layer A3 of the third transistor T3 may include a channel area C3 overlapping the seventh conductive pattern 1620 and conductive areas S3 and D3 disposed on both sides of the channel area C3. One of the conductive areas S3 and D3 may be a source area, and the other one may be a drain area. The source area and the drain area may respectively correspond to a source electrode and a drain electrode. The positions of the source area and the drain area may be interchanged with each other depending on the properties of the transistor.

Referring to FIG. 14, a fifth conductive layer 1700 may be disposed on the fourth conductive layer 1600. The fifth conductive layer 1700 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The fifth conductive layer 1700 may include a second scan line GWL2, a second horizontal reference voltage line HVRL2, a reference gate line GRL, a second horizontal driving voltage line HPL2, a first horizontal initialization voltage line HVL1, a second horizontal initialization voltage line HVL2, a horizontal common voltage line HVSL, and eighth to 14th conductive patterns 1710, 1720, 1730, 1740, 1750, 1760, and 1770. The second scan line GWL2, the second horizontal reference voltage line HVRL2, the reference gate line GRL, the second horizontal driving voltage line HPL2, the first horizontal initialization voltage line HVL1, the second horizontal initialization voltage line HVL2, the horizontal common voltage line HVSL, and the eighth to 14th conductive patterns 1710, 1720, 1730, 1740, 1750, 1760, and 1770 may be spaced apart from each other.

The second scan line GWL2 may extend in the first direction (e.g., x-axis direction) to pass through the first pixel circuit PC1, the second pixel circuit PC2, and the third pixel circuit PC3. The second scan line GWL2 may pass through the pixel circuits disposed in the same row as the first pixel circuit PC1, the second pixel circuit PC2, and the third pixel circuit PC3. The second scan line GWL2 may overlap the first scan line GWL1 (see FIG. 13) and may be electrically connected to the first scan line GWL1 (see FIG. 13) through a first contact hole CNT1.

The second horizontal reference voltage line HVRL2 may extend in the first direction (e.g., x-axis direction) to pass through the first pixel circuit PC1, the second pixel circuit PC2, and the third pixel circuit PC3. The second horizontal reference voltage line HVRL2 may pass through the pixel circuits disposed in the same row as the first pixel circuit PC1, the second pixel circuit PC2, and the third pixel circuit PC3. The second horizontal reference voltage line HVRL2 may overlap the first horizontal reference voltage line HVRL1 (see FIG. 8).

The second horizontal reference voltage line HVRL2 may be electrically connected to the first horizontal reference voltage line HVRL1 (see FIG. 8) through a second contact hole CNT2 and may be electrically connected to the dummy horizontal reference voltage line HVRLd (see FIG. 11) through a third contact hole CNT3. For example, the first horizontal reference voltage line HVRL1, the dummy horizontal reference voltage line HVRLd, and the second horizontal reference voltage line HVRL2 may be electrically connected to each other to transmit a reference voltage to each pixel circuit. Also, the second horizontal reference voltage line HVRL2 may be connected to the second oxide semiconductor pattern 1510 (see FIG. 12) through a fourth contact hole CNT4 to transmit a reference voltage to the third transistor T3 (see FIG. 13).

The reference gate line GRL may extend in the first direction (e.g., x-axis direction) to pass through the first pixel circuit PC1, the second pixel circuit PC2, and the third pixel circuit PC3. The reference gate line GRL may pass through the pixel circuits disposed in the same row as the first pixel circuit PC1, the second pixel circuit PC2, and the third pixel circuit PC3. The reference gate line GRL may be electrically connected to the seventh conductive pattern 1620 (see FIG. 13) through a contact hole to transmit a reference signal to the gate electrode of the third transistor T3 (see FIG. 13). For example, the reference gate line GRL may be electrically connected to the seventh-1 conductive pattern 1620a (see FIG. 13) through a fifth-1 contact hole CNT5a and a fifth-2 contact hole CNT5b and may be electrically connected to the seventh-2 conductive pattern 1620b (see FIG. 13) through a fifth-3 contact hole CNT5c.

The eighth conductive pattern 1710 located in each of the first pixel circuit PC1, the second pixel circuit PC2, and the third pixel circuit PC3 may have an isolated shape. The eighth conductive pattern 1710 of the first pixel circuit PC1 and the eighth conductive pattern 1710 of the second pixel circuit PC2 may be symmetrically disposed with respect to the imaginary line IML1, and the eighth conductive pattern 1710 of the second pixel circuit PC2 and the eighth conductive pattern 1710 of the third pixel circuit PC3 may be symmetrically disposed with respect to the imaginary line IML2.

The eighth conductive pattern 1710 may be a connection electrode connecting the first oxide semiconductor pattern 1510 (see FIG. 12) including the second semiconductor layer A2 (see FIG. 12) to the data line DL (see FIG. 15). The eighth conductive pattern 1710 may be connected to one end of the first oxide semiconductor pattern 1510 (see FIG. 12) through a sixth contact hole CNT6.

The ninth conductive pattern 1720 located in each of the first pixel circuit PC1, the second pixel circuit PC2, and the third pixel circuit PC3 may have an isolated shape. The ninth conductive pattern 1720 of the first pixel circuit PC1 and the ninth conductive pattern 1720 of the second pixel circuit PC2 may be symmetrically disposed with respect to the imaginary line IML1, and the ninth conductive pattern 1720 of the second pixel circuit PC2 and the ninth conductive pattern 1720 of the third pixel circuit PC3 may be symmetrically disposed with respect to the imaginary line IML2.

The ninth conductive pattern 1720 may be a connection electrode connecting the first oxide semiconductor pattern 1510 (see FIG. 12) including the second semiconductor layer A2 (see FIG. 12) and the third semiconductor layer A3 (see FIG. 12) to the sixth conductive pattern 1610 (see FIG. 13) including the first upper gate electrode G1a (see FIG. 13) of the first transistor T1 (see FIG. 13). For example, the ninth conductive pattern 1720 may be a first node electrode connecting the first transistor T1 (see FIG. 13), the second transistor T2 (see FIG. 13), and the third transistor T3 (see FIG. 13). (Here, the first node electrode may correspond to the first node N1 of FIG. 5.) The ninth conductive pattern 1720 may be connected to the first oxide semiconductor pattern 1510 (see FIG. 12) through a seventh contact hole CNT7 and may be connected to the sixth conductive pattern 1610 (see FIG. 13) through a ninth contact hole CNT9.

Also, the ninth conductive pattern 1720 may also be electrically connected to the storage capacitor Cst (see FIG. 6). The ninth conductive pattern 1720 may be connected to the first storage electrode CEs1 (see FIG. 9) of the storage capacitor Cst (see FIG. 6) through an eighth contact hole CNT8.

The 10th conductive pattern 1730 located in each of the first pixel circuit PC1, the second pixel circuit PC2, and the third pixel circuit PC3 may have an isolated shape. The 10th conductive pattern 1730 may overlap the third conductive pattern 1310 (see FIG. 10). The 10th conductive pattern 1730 of the first pixel circuit PC1 and the 10th conductive pattern 1730 of the second pixel circuit PC2 may be symmetrically disposed with respect to the imaginary line IML1, and the 10th conductive pattern 1730 of the second pixel circuit PC2 and the 10th conductive pattern 1730 of the third pixel circuit PC3 may be symmetrically disposed with respect to the imaginary line IML2.

The 10th conductive pattern 1730 may be a connection electrode connecting the second oxide semiconductor pattern 1520 (see FIG. 12) including the first semiconductor layer A1 (see FIG. 12) to the third oxide semiconductor pattern 1530 (see FIG. 12) including the sixth semiconductor layer A6 (see FIG. 12). For example, the 10th conductive pattern 1730 may be a second node electrode connecting the first transistor T1 (see FIG. 13) and the sixth transistor T6 (see FIG. 13). (Here, the second node electrode may correspond to the second node N2 of FIG. 5.) The 10th conductive pattern 1730 may be connected to the second oxide semiconductor pattern 1520 (see FIG. 12) through a 12th contact hole CNT12 and may be connected to the third oxide semiconductor pattern 1530 (see FIG. 12) through a 13th contact hole CNT13.

Also, the 10th conductive pattern 1730 may also be electrically connected to the storage capacitor Cst (see FIG. 6), the hold capacitor Chd (see FIG. 6), and the first lower gate electrode G1b (see FIG. 11) of the first transistor T1 (see FIG. 13). The 10th conductive pattern 1730 may be electrically connected to the third conductive pattern 1310 (see FIG. 10) including the second storage electrode CEs2 (see FIG. 10) and the second hold electrode CEh2 (see FIG. 10) through a 10th contact hole CNT10. The 10th conductive pattern 1730 may be electrically connected to the fourth conductive pattern 1410 (see FIG. 11) including the first lower gate electrode G1b (see FIG. 11) through an 11th contact hole CNT11.

The 11th conductive pattern 1740 located in each of the first pixel circuit PC1, the second pixel circuit PC2, and the third pixel circuit PC3 may have an isolated shape. The 11th conductive pattern 1740 may have a shape extending in the first direction (e.g., x-axis direction). The 11th conductive pattern 1740 of the first pixel circuit PC1 and the 11th conductive pattern 1740 of the second pixel circuit PC2 may be symmetrically disposed with respect to the imaginary line IML1, and the 11th conductive pattern 1740 of the second pixel circuit PC2 and the 11th conductive pattern 1740 of the third pixel circuit PC3 may be symmetrically disposed with respect to the imaginary line IML2.

The 11th conductive pattern 1740 may be a connection electrode connecting the second oxide semiconductor pattern 1520 (see FIG. 12) including the first semiconductor layer A1 (see FIG. 12) to the first silicon semiconductor pattern 1110 (see FIG. 8) including the fifth semiconductor layer A5 (see FIG. 8). One end of the 11th conductive pattern 1740 may be electrically connected to the second oxide semiconductor pattern 1520 (see FIG. 12) through a 14th contact hole CNT14, and the other end of the 11th conductive pattern 1740 may be electrically connected to the first silicon semiconductor pattern 1110 (see FIG. 8) through a 15th contact hole CNT15.

The 12th conductive pattern 1750 may extend in the first direction (e.g., x-axis direction) to pass through the first pixel circuit PC1, the second pixel circuit PC2, and the third pixel circuit PC3. The 12th conductive pattern 1750 may pass through the pixel circuits disposed in the same row as the first pixel circuit PC1, the second pixel circuit PC2, and the third pixel circuit PC3. The 12th conductive pattern 1750 may be electrically connected to the first vertical driving voltage line VPL1 (see FIG. 15), the second vertical driving voltage line VPL2 (see FIG. 15), and the first horizontal driving voltage line HPL1 (see FIG. 9) described below, to transmit a driving voltage to each pixel circuit. Thus, the 12th conductive pattern 1750 may also be referred to as a second horizontal driving voltage line HPL2.

For example, the 12th conductive pattern 1750 may include a stem portion 1750t extending in the first direction (e.g., x-axis direction) and a branch portion 1750b branching from the stem portion 1750t and extending in the second direction (e.g., y-axis direction). The branch portion 1750b of the 12th conductive pattern 1750 may include a first branch portion 1750bl overlapping the first branch portion 1220b1 (see FIG. 9) of the first horizontal driving voltage line HPL1 (see FIG. 9) and a second branch portion 1750b2 overlapping the second branch portion 1220b2 (see FIG. 9) of the first horizontal driving voltage line HPL1 (see FIG. 9). For example, the first branch portion 1750bl of the 12th conductive pattern 1750 may refer to a partial area of the 12th conductive pattern 1750 that branches from the end of the stem portion 1750t and extends in the second direction (e.g., y-axis direction). The second branch portion 1750b2 of the 12th conductive pattern 1750 may refer to a partial area of the 12th conductive pattern 1750 that branches from the stem portion 1750t and extends in the second direction (e.g., y-axis direction) on the imaginary line IML2 and is disposed across the second pixel circuit PC2 and the third pixel circuit PC3.

The stem portion 1750t of the 12th conductive pattern 1750 may receive a driving voltage from the first vertical driving voltage line VPL1 (see FIG. 15) and the second vertical driving voltage line VPL2 (see FIG. 15) described below to be electrically connected to the first silicon semiconductor pattern 1110 (see FIG. 8) through a 17th contact hole CNT17. Accordingly, the 12th conductive pattern 1750, for example, the second horizontal driving voltage line HPL2, may be configured to transmit a driving voltage to the fifth transistor T5 (see FIG. 9).

Also, the first branch portion 1750bl of the 12th conductive pattern 1750 may be electrically connected to the first branch portion 1220b1 (see FIG. 9) of the second conductive pattern 1220 (see FIG. 9) through a 16th-1 contact hole CNT16a. The second branch portion 1750b2 of the 12th conductive pattern 1750 may be electrically connected to the second branch portion 1220b2 (see FIG. 9) of the second conductive pattern 1220 (see FIG. 9) through a 16th-2 contact hole CNT16b. Accordingly, the 12th conductive pattern 1750, for example, the second horizontal driving voltage line HPL2, may be configured to transmit a driving voltage to the first horizontal driving voltage line HPL1 (see FIG. 9), and the first horizontal driving voltage line HPL1 (see FIG. 9) may be configured to transmit a driving voltage to the first hold electrode CEh1 (see FIG. 9) of the hold capacitor Chd (see FIG. 6).

The 13th conductive pattern 1760 located in each of the first pixel circuit PC1, the second pixel circuit PC2, and the third pixel circuit PC3 may have an isolated shape. The 13th conductive pattern 1760 may have a shape extending in the first direction (e.g., x-axis direction). A 13th-1 conductive pattern 1760a of the first pixel circuit PC1 and a 13th-2 conductive pattern 1760b of the second pixel circuit PC2 may be symmetrically disposed with respect to the imaginary line IML1. A 13th-3 conductive pattern 1760c of the third pixel circuit PC3 may further include a protrusion portion extending diagonally in the same shape as the 13th-1 conductive pattern 1760a of the first pixel circuit PC1. The protrusion portion of the 13th-3 conductive pattern 1760c may be for connection to the 16th conductive pattern 1820 (see FIG. 15) described below.

The 13th conductive pattern 1760 may be a connection electrode connecting the third oxide semiconductor pattern 1530 (see FIG. 12) including the fourth semiconductor layer A4 (see FIG. 12) and the sixth semiconductor layer A6 (see FIG. 12) to the light emitting diode LED (see FIG. 7). For example, the 13th conductive pattern 1760 may be electrically connected to the third oxide semiconductor pattern 1530 (see FIG. 12) through a 19th contact hole CNT19 and may be electrically connected to the light emitting diode LED (see FIG. 7) through the 16th conductive pattern 1820 (see FIG. 15) described below. For example, the 13th conductive pattern 1760 may be a pixel connection electrode that connects the fourth transistor T4 (see FIG. 13) and the sixth transistor T6 (see FIG. 13) to the light emitting diode LED (see FIG. 7). Thus, the 13th conductive pattern 1760 may also be referred to as a first pixel connection electrode.

Moreover, the 13th conductive pattern 1760 may overlap the repair line RPL (see FIG. 10) and the fifth conductive pattern 1420 (see FIG. 11). As described above, in the case of a defective pixel circuit, in a repair process, the 13th conductive pattern 1760, which is a pixel connection electrode, and the third oxide semiconductor pattern 1530 (see FIG. 12) may be insulated from each other and the 13th conductive pattern 1760 and the repair line RPL (see FIG. 10) may be connected to each other to receive a normal driving current from the dummy circuit. The fifth conductive pattern 1420 (see FIG. 11), which is a repair bridge pattern, may be disposed between the 13th conductive pattern 1760 and the repair line RPL (see FIG. 10). The 13th conductive pattern 1760 may be electrically connected to the fifth conductive pattern 1420 (see FIG. 11) through an 18th contact hole CNT18, and the repair line RPL (see FIG. 10) and the fifth conductive pattern 1420 (see FIG. 11) may be short-circuited during a repair process. For example, as a pixel connection electrode, a portion of the 13th conductive pattern 1760 may overlap the third oxide semiconductor pattern 1530 (see FIG. 12), and another portion of the 13th conductive pattern 1760 may overlap the fifth conductive pattern 1420 (see FIG. 11).

The first horizontal initialization voltage line HVL1 and the second horizontal initialization voltage line HVL2 may extend in the first direction (e.g., x-axis direction) to pass through the first pixel circuit PC1, the second pixel circuit PC2, and the third pixel circuit PC3. The first horizontal initialization voltage line HVL1 and the second horizontal initialization voltage line HVL2 may pass through the pixel circuits disposed in the same row as the first pixel circuit PC1, the second pixel circuit PC2, and the third pixel circuit PC3. The first horizontal initialization voltage line HVL1 may be electrically connected to the third oxide semiconductor pattern 1530 (see FIG. 12) of the first pixel circuit PC1 through a 20th-1 contact hole CNT20a to transmit an initialization voltage to the fourth transistor T4 (see FIG. 13) of the first pixel circuit PC1. The second horizontal initialization voltage line HVL2 may be electrically connected to the third oxide semiconductor pattern 1530 (see FIG. 12) of the second pixel circuit PC2 through a 20th-2 contact hole CNT20b to transmit an initialization voltage to the fourth transistor T4 (see FIG. 13) of the second pixel circuit PC2.

The 14th conductive pattern 1770 may have an isolated shape and may be disposed on the imaginary line IML2 that is the boundary between the second pixel circuit PC2 and the third pixel circuit PC3. The 14th conductive pattern 1770 may have a shape extending in the first direction (e.g., x-axis direction). The 14th conductive pattern 1770 may be a connection electrode connecting the third oxide semiconductor pattern 1530 (see FIG. 12) of the third pixel circuit PC3 to the third horizontal initialization voltage line HVL3 (see FIG. 13). The 14th conductive pattern 1770 may be electrically connected to the third oxide semiconductor pattern 1530 (see FIG. 12) through a 20th-3 contact hole CNT20c and electrically connected to the third horizontal initialization voltage line HVL3 (see FIG. 13) through a 20th-4 contact hole CNT20d to transmit the initialization voltage to the fourth transistor T4 (see FIG. 13) of the third pixel circuit PC3.

The horizontal common voltage line HVSL may extend in the first direction (e.g., x-axis direction) to pass through the first pixel circuit PC1, the second pixel circuit PC2, and the third pixel circuit PC3. The horizontal common voltage line HVSL may pass through the pixel circuits disposed in the same row as the first pixel circuit PC1, the second pixel circuit PC2, and the third pixel circuit PC3. The horizontal common voltage line HVSL may be electrically connected to the first vertical common voltage line VVSL1 (see FIG. 15) or the second vertical common voltage line VVSL2 (see FIG. 15) described below, to transmit a common voltage to the light emitting diode LED (see FIG. 8).

Referring to FIG. 15, a sixth conductive layer 1800 may be disposed on the fifth conductive layer 1700. The sixth conductive layer 1800 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may include a single layer or multiple layers of the above material.

The sixth conductive layer 1800 may include a data line DL, a vertical driving voltage line VPL, a vertical initialization voltage line VVL (or a second vertical common voltage line), a first vertical common voltage line VVSL1 (or a vertical reference voltage line), a 15th conductive pattern 1810, and a 16th conductive pattern 1820. The data line DL, the vertical driving voltage line VPL, the vertical initialization voltage line VVL, the first vertical common voltage line VVSL1, the 15th conductive pattern 1810, and the 16th conductive pattern 1820 may be spaced apart from each other.

The data line DL may extend in the second direction (e.g., y-axis direction). The data line DL may include a first data line DL1 electrically connected to the first pixel circuit PC1, a second data line DL2 electrically connected to the second pixel circuit PC2, and a third data line DL3 electrically connected to the third pixel circuit PC3. The data line DL may be electrically connected through a 21st contact hole CNT21 to the eighth conductive pattern 1710 (see FIG. 14) connected to the first oxide semiconductor pattern 1510 (see FIG. 12). For example, the data line DL may be configured to transmit a data signal to the second semiconductor layer A2 (see FIG. 12) through the eighth conductive pattern 1710 (see FIG. 14).

The first data line DL1 may pass through the first pixel circuit PC1, the second data line DL2 may pass through the second pixel circuit PC2, and the third data line DL3 may pass through the third pixel circuit PC3 except for some areas. The first data line DL1 may be disposed on the left side of the first vertical driving voltage line VPL1. The second data line DL2 and the third data line DL3 may be disposed in parallel between the second vertical driving voltage line VPL2 and the vertical reference voltage line VVRL (or the second vertical common voltage line).

The vertical driving voltage line VPL may extend in the second direction (e.g., y-axis direction). The vertical driving voltage line VPL may include a first vertical driving voltage line VPL1 disposed on the first pixel circuit PC1 and a second vertical driving voltage line VPL2 disposed on the second pixel circuit PC2. The first vertical driving voltage line VPL1 and the second vertical driving voltage line VPL2 may be symmetrically disposed with respect to the imaginary line IML1. The first vertical driving voltage line VPL1 may be electrically connected to the second horizontal driving voltage line HPL2 (see FIG. 14) through a 22nd-1 contact hole CNT22a, and the second vertical driving voltage line VPL2 may be electrically connected to the second horizontal driving voltage line HPL2 (see FIG. 14) through a 22nd-2 contact hole CNT22b.

The vertical initialization voltage line VVL may extend in the second direction (e.g., y-axis direction). The vertical initialization voltage line VVL may be disposed between the first vertical driving voltage line VPL1 and the second vertical driving voltage line VPL2. The vertical initialization voltage line VVL may be disposed on the imaginary line IML1 that is the boundary between the first pixel circuit PC1 and the second pixel circuit PC2. The vertical initialization voltage line VVL may be electrically connected to the first horizontal initialization voltage line HVL1 (see FIG. 14) through a 23rd contact hole CNT23. In some embodiments, the vertical initialization voltage line VVL may also function as the second vertical common voltage line VVSL2 depending on the connection relationship.

The first vertical common voltage line VVSL1 may extend in the second direction (e.g., y-axis direction). The first vertical common voltage line VVSL1 may be disposed on the third pixel circuit PC3. The first vertical common voltage line VVSL1 may be electrically connected to the horizontal common voltage line HVSL (see FIG. 14) through a 24th contact hole CNT24 and may be electrically connected to the light emitting diode LED (see FIG. 7) through a 28th contact hole CNT28. For example, the horizontal common voltage line HVSL (see FIG. 14) and the first vertical common voltage line VVSL1 may be electrically connected to the common voltage line 16 (see FIG. 3) disposed in the peripheral area PA (see FIG. 3), to transmit a common voltage to the light emitting diode LED (see FIG. 7). In some embodiments, the first vertical common voltage line VVSL1 may also function as the vertical reference voltage line VVRL depending on the connection relationship.

Each of the 15th conductive pattern 1810 and the 16th conductive pattern 1820 may have an isolated shape. Each of the 15th conductive pattern 1810 and the 16th conductive pattern 1820 may be disposed in the first pixel circuit PC1, the second pixel circuit PC2, and the third pixel circuit PC3. The 15th conductive pattern 1810 may be electrically connected to the 10th conductive pattern 1730 (see FIG. 14) through a 25th contact hole CNT25 and may have a shape extended in the second direction (e.g., y-axis direction) to cover the ninth conductive pattern 1720 (see FIG. 14). Because the 15th conductive pattern 1810 shields the ninth conductive pattern 1720 (see FIG. 14) electrically connected to the storage capacitor Cst (see FIG. 6), the image quality characteristics may be improved.

The 16th conductive pattern 1820 may be a connection electrode connecting the third oxide semiconductor pattern 1530 (see FIG. 12) to the light emitting diode LED (see FIG. 7). The 16th conductive pattern 1820 may be electrically connected to the 13th conductive pattern 1760 (see FIG. 14) through a 26th contact hole CNT26 and may be electrically connected to the pixel electrode 210 (see FIG. 7) of the light emitting diode LED (see FIG. 7) through a 27th contact hole CNT27. Thus, the 16th conductive pattern 1820 may also be referred to as a second pixel connection electrode.

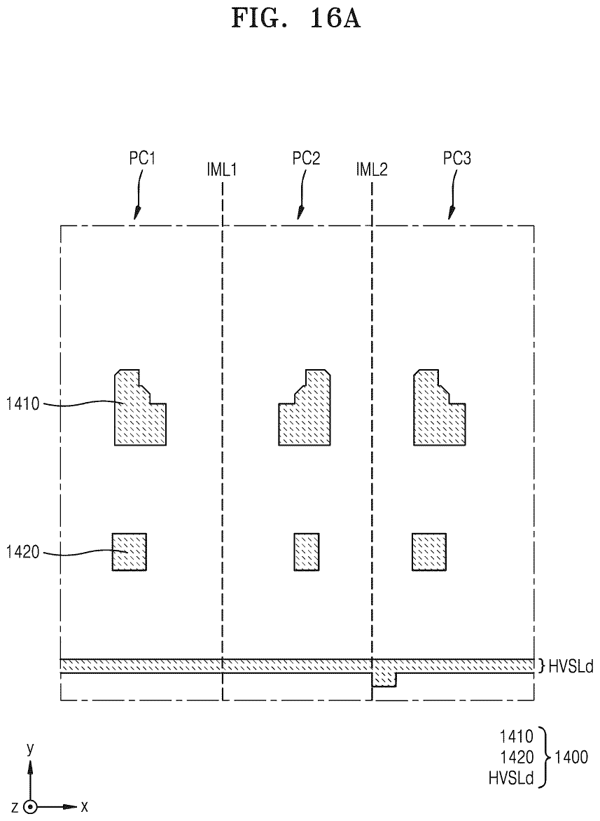

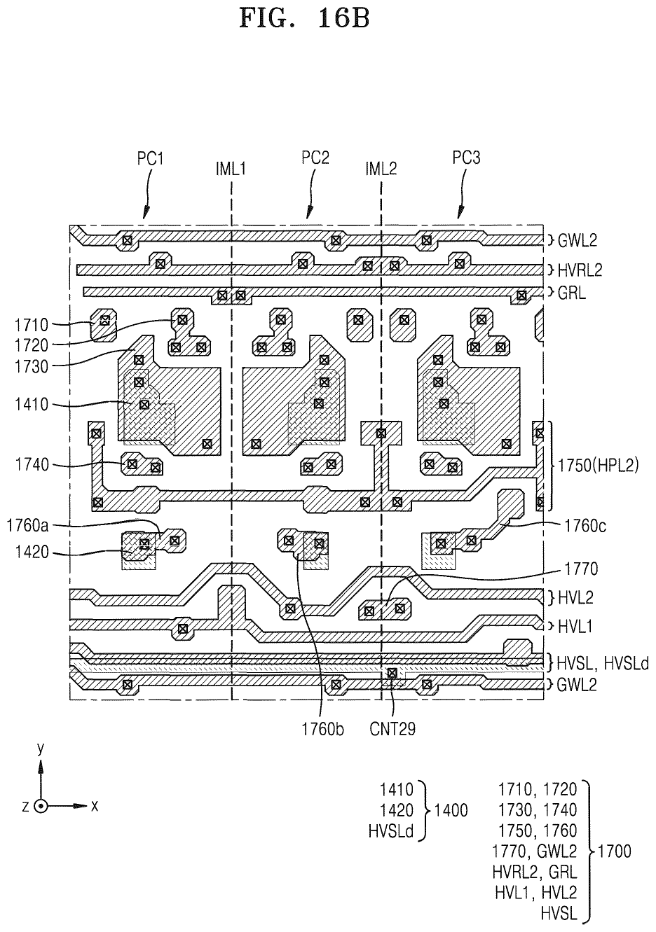

FIGS. 16A and 16B are plan views schematically illustrating pixel circuits of a display apparatus according to an embodiment of the disclosure.

Referring to FIGS. 16A and 16B, the third conductive layer 1400 may include a fourth conductive pattern 1410, a fifth conductive pattern 1420, and a dummy horizontal common voltage line HVSLd. The fourth conductive pattern 1410, the fifth conductive pattern 1420, and the dummy horizontal common voltage line HVSLd may be spaced apart from each other. Moreover, the fifth conductive layer 1700 may include a second scan line GWL2, a second horizontal reference voltage line HVRL2, a reference gate line GRL, a second horizontal driving voltage line HPL2, a first horizontal initialization voltage line HVL1, a second horizontal initialization voltage line HVL2, a horizontal common voltage line HVSL, and eighth to 14th conductive patterns 1710, 1720, 1730, 1740, 1750, 1760, and 1770.

The dummy horizontal common voltage line HVSLd may extend in the first direction (e.g., x-axis direction) to pass through the first pixel circuit PC1, the second pixel circuit PC2, and the third pixel circuit PC3. The dummy horizontal common voltage line HVSLd may pass through the pixel circuits disposed in the same row as the first pixel circuit PC1, the second pixel circuit PC2, and the third pixel circuit PC3. The dummy horizontal common voltage line HVSLd may partially overlap the horizontal common voltage line HVSLd in the plan view. The dummy horizontal common voltage line HVSLd may be electrically connected to the horizontal common voltage line HVSLd through a 29th contact hole CNT29.

Like the dummy horizontal common voltage line HVSLd, the third conductive layer 1400 may include a dummy line electrically connected to at least one of the plurality of voltage lines. As described above, when the pattern density of a particular layer is low, the pattern may be nonuniformly deposited or a process problem such as an exposure failure, overetching, or underetching may occur. Accordingly, in the display apparatus, according to an embodiment of the disclosure, the dummy horizontal common voltage line HVSLd may be disposed in the third conductive layer 1400 having a relatively low pattern density to increase the pattern density of the third conductive layer 1400 and improve the stability of the display apparatus manufacturing process.

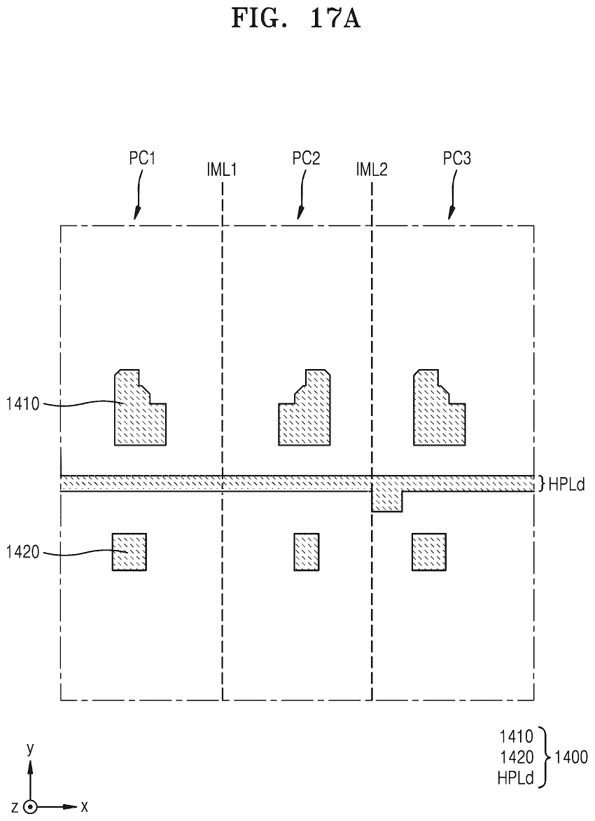

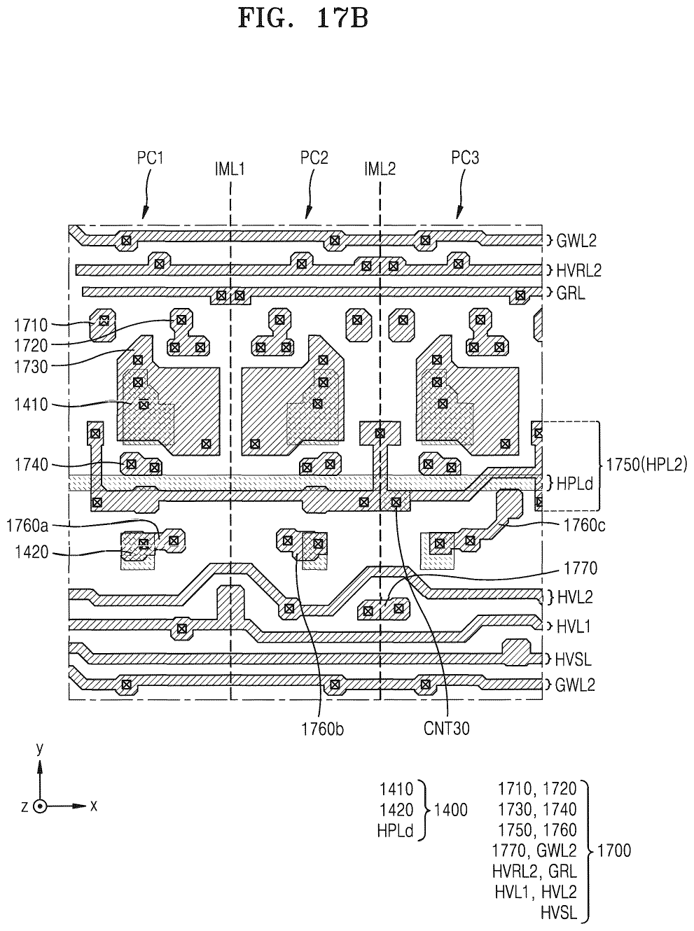

FIGS. 17A and 17B are plan views schematically illustrating pixel circuits of a display apparatus according to an embodiment of the disclosure.

Referring to FIGS. 17A and 17B, the third conductive layer 1400 may include a fourth conductive pattern 1410, a fifth conductive pattern 1420, and a dummy horizontal driving voltage line HPLd. The fourth conductive pattern 1410, the fifth conductive pattern 1420, and the dummy horizontal driving voltage line HPLd may be spaced apart from each other. Moreover, the fifth conductive layer 1700 may include a second scan line GWL2, a second horizontal reference voltage line HVRL2, a reference gate line GRL, a second horizontal driving voltage line HPL2, a first horizontal initialization voltage line HVL1, a second horizontal initialization voltage line HVL2, a horizontal common voltage line HVSL, and eighth to 14th conductive patterns 1710, 1720, 1730, 1740, 1750, 1760, and 1770.

The dummy horizontal driving voltage line HPLd may extend in the first direction (e.g., x-axis direction) to pass through the first pixel circuit PC1, the second pixel circuit PC2, and the third pixel circuit PC3. The dummy horizontal driving voltage line HPLd may pass through the pixel circuits disposed in the same row as the first pixel circuit PC1, the second pixel circuit PC2, and the third pixel circuit PC3. The dummy horizontal driving voltage line HPLd may partially overlap the second horizontal driving voltage line HPL2 in the plan view. The dummy horizontal driving voltage line HPLd may be electrically connected to the second horizontal driving voltage line HPL2 through a 30th contact hole CNT30.

Like the dummy horizontal driving voltage line HPLd, the third conductive layer 1400 may include a dummy line electrically connected to at least one of the plurality of voltage lines. As described above, when the pattern density of a particular layer is low, the pattern may be nonuniformly deposited or a process problem such as an exposure failure, overetching, or underetching may occur. Accordingly, in the display apparatus according to an embodiment of the disclosure, the dummy horizontal driving voltage line HPLd may be disposed in the third conductive layer 1400 having a relatively low pattern density to increase the pattern density of the third conductive layer 1400 and improve the stability of the display apparatus manufacturing process.

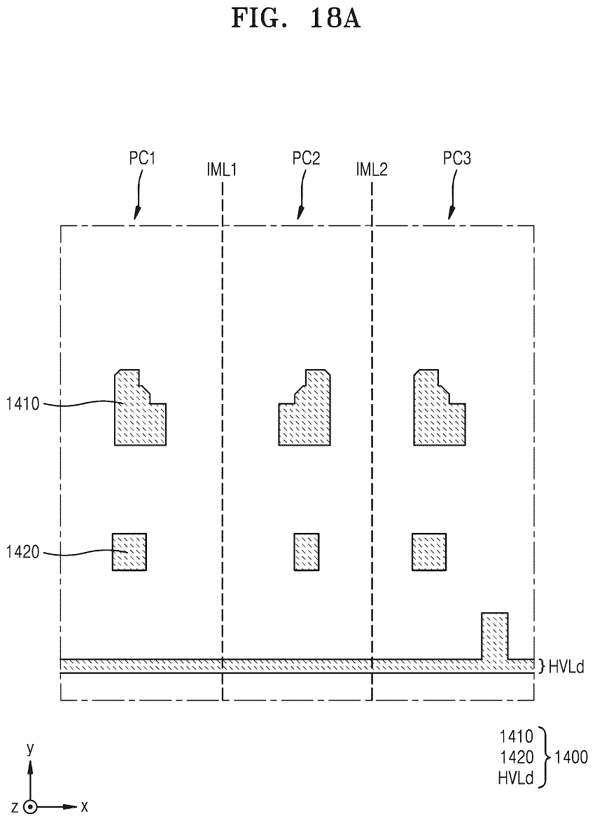

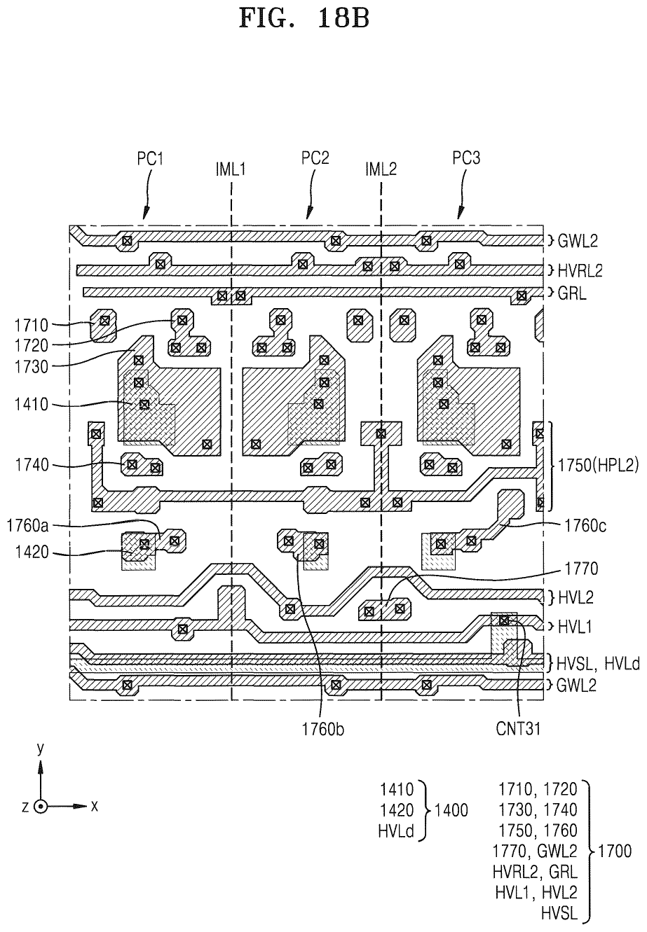

FIGS. 18A and 18B are plan views schematically illustrating pixel circuits of a display apparatus according to an embodiment of the disclosure.

Referring to FIGS. 18A and 18B, the third conductive layer 1400 may include a fourth conductive pattern 1410, a fifth conductive pattern 1420, and a dummy horizontal initialization voltage line HVLd. The fourth conductive pattern 1410, the fifth conductive pattern 1420, and the dummy horizontal initialization voltage line HVLd may be spaced apart from each other. Moreover, the fifth conductive layer 1700 may include a second scan line GWL2, a second horizontal reference voltage line HVRL2, a reference gate line GRL, a second horizontal driving voltage line HPL2, a first horizontal initialization voltage line HVL1, a second horizontal initialization voltage line HVL2, a horizontal common voltage line HVSL, and eighth to 14th conductive patterns 1710, 1720, 1730, 1740, 1750, 1760, and 1770.

The dummy horizontal initialization voltage line HVLd may extend in the first direction (e.g., x-axis direction) to pass through the first pixel circuit PC1, the second pixel circuit PC2, and the third pixel circuit PC3. The dummy horizontal initialization voltage line HVLd may pass through the pixel circuits disposed in the same row as the first pixel circuit PC1, the second pixel circuit PC2, and the third pixel circuit PC3. The dummy horizontal initialization voltage line HVLd may further include a protrusion portion extending to partially overlap the first horizontal initialization voltage line HVL1 in the plan view. The dummy horizontal initialization voltage line HVLd may be electrically connected to the first horizontal initialization voltage line HVL1 through a 31st contact hole CNT31. In an embodiment, the dummy horizontal initialization voltage line HVLd may be electrically connected to the second horizontal initialization voltage line HVL2 or the third horizontal initialization voltage line HVL3 (see FIG. 13).

Like the dummy horizontal initialization voltage line HVLd, the third conductive layer 1400 may include a dummy line electrically connected to at least one of the plurality of voltage lines. As described above, when the pattern density of a particular layer is low, the pattern may be nonuniformly deposited or a process problem such as an exposure failure, overetching, or underetching may occur. Accordingly, in the display apparatus according to an embodiment of the disclosure, the dummy horizontal initialization voltage line HVLd may be disposed in the third conductive layer 1400 having a relatively low pattern density to increase the pattern density of the third conductive layer 1400 and improve the stability of the display apparatus manufacturing process.

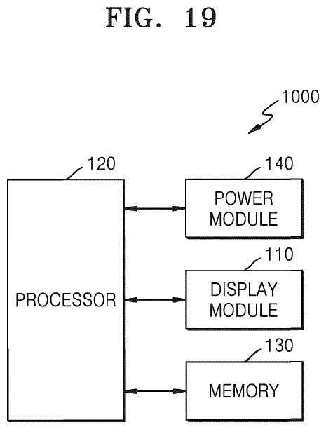

FIG. 19 is a block diagram of an electronic apparatus according to an embodiment of the disclosure.

Referring to FIG. 19, an electronic apparatus 1000, according to an embodiment, may include a display module 110, a processor 120, a memory 130, and a power module 140.

The electronic apparatus 1000 may output various types of information in an operating system through the display module 110.

The processor 120 may include at least one of a central processing unit (CPU), an application processor (AP), a graphic processing unit (GPU), a communication processor (CP), an image signal processor (ISP), and a controller. In an embodiment, the processor 120 may be divided into two or more processors from a functional or structural viewpoint. For example, the processor 120 may include a main processor in the form of a first driving chip including a CPU, and an auxiliary processor in the form of a second driving chip including a controller that receives an image signal from the main processor and processes the image signal in accordance with the interface specifications of the display module 110.

The memory 130 may include at least one of a nonvolatile memory and a volatile memory. The memory 130 may store data information necessary for the operation of the processor 120 or the display module 110. When the processor 120 executes an application stored in the memory 130, an image data signal and/or an input control signal may be transmitted to the display module 110 and the display module 110 may process the received signal and output image information through a display screen.

The power module 140 may include a power supply module such as a power adapter or a battery device, and a power conversion module that converts the power supplied by the power supply module to generate power necessary for the operation of the electronic apparatus 1000. The power conversion by the power conversion module may include, but is not necessarily limited to, DC-DC conversion, AC-DC conversion, and DC-AC conversion.

At least one of the components of the electronic apparatus 1000 described above may be included in the display apparatus according to the embodiments described above. Also, some of the individual modules functionally included in one module may be included in the display apparatus, and some others thereof may be provided separately from the display apparatus. For example, the display apparatus may include the display module 110 and the auxiliary processor of the processor 120, and the main processor of the processor 120, the memory 130, and the power module 140 may be provided in the form of other devices in the electronic apparatus 1000, not in the display apparatus. As an example, the power module 140 may be disposed in the display apparatus and may supply power to the processor 120 and the memory 130 provided in the electronic apparatus 1000, not in the display apparatus; however, the disclosure is not necessarily limited thereto.

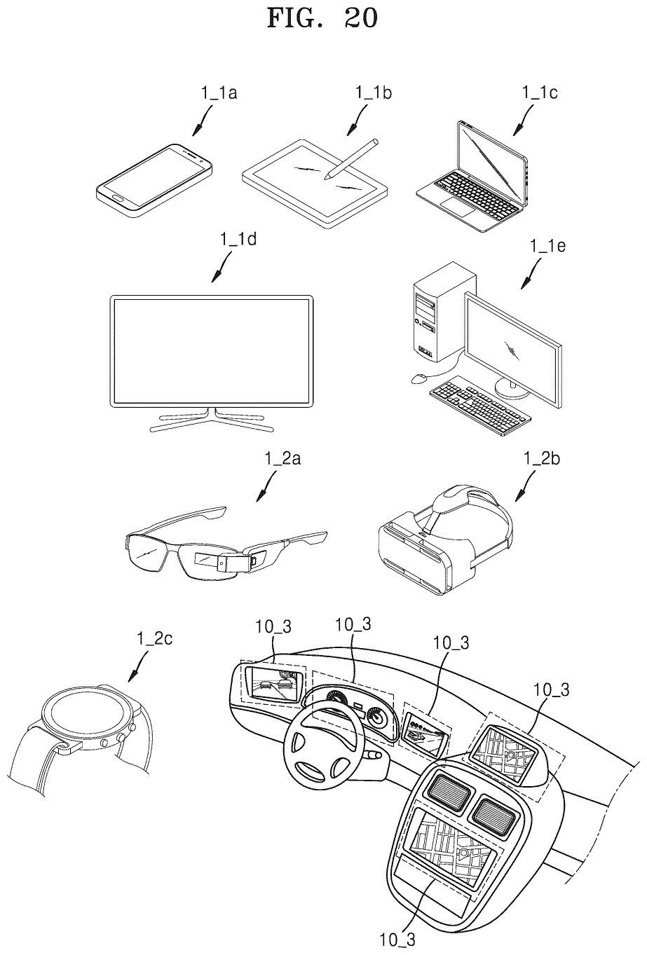

FIG. 20 is a schematic diagram of electronic apparatuses according to various embodiments of the disclosure.

The display apparatus, according to embodiments of the disclosure, may be an apparatus that displays moving images or still images, and may be applied to various electronic apparatuses. Referring to FIG. 20, various electronic apparatuses including the display apparatus according to embodiments may include not only an electronic apparatus for displaying images, such as a smart phone 1_1a, a tablet computer 1_1b, a laptop/notebook computer 1_1c, a television (TV) 1_1d, or a computer monitor 1_1e, but also a wearable electronic apparatus including a display module, such as smart glasses 1_2a, a head-mounted display 1_2b, or a smart watch 1_2c, and a vehicle electronic apparatus 10_3 including a display module, such as a center information display (CID) or a room mirror display disposed in the instrument panel, center fascia, or dashboard of a car. The electronic apparatus 1000, according to embodiments of the disclosure, is not necessarily limited to the above apparatuses.

The electronic apparatus of FIG. 20 may include the components illustrated in FIG. 19. For example, the smart phone 1_1a may include the display module 110, the processor 120, the memory 130, and the power module 140 illustrated in FIG. 19. The smart phone 1_1a may further include a communication module and a battery device. The power provided by the battery device may be converted through the power module 140 and provided to the processor 120, the memory 130, and the display module 110. In an embodiment, the display apparatus included in the smart phone 1_1a may include the display module 110 and may further include the power module 140. The processor 120 and the memory 130 may be provided in the form of a chip mounted on a motherboard, which is an external device; however, the disclosure is not necessarily limited thereto.

Although the disclosure has been described with reference to an embodiment illustrated in the drawings, this is an example and those of ordinary skill in the art will understand that various modifications may be made therein.

What is claimed is:

1. A display apparatus, comprising:
a substrate;
a first pixel circuit disposed on the substrate and comprising a driving transistor and a storage capacitor;
a light emitting diode electrically connected to the first pixel circuit; and
a repair line disposed on the substrate and extending in a first direction,
wherein the first pixel circuit further comprises:
a first pixel connection electrode electrically connected to a pixel electrode of the light emitting diode; and
a repair bridge pattern disposed between the repair line and the first pixel connection electrode, and
wherein, in a plan view, the repair bridge pattern overlaps the repair line and the first pixel connection electrode.

2. The display apparatus of claim 1, wherein the first pixel circuit further comprises:
a first conductive pattern disposed on the substrate and comprising a first electrode of the storage capacitor;
a second conductive pattern disposed on the first conductive pattern and overlapping the first conductive pattern and comprising a second electrode of the storage capacitor;
a third conductive pattern disposed on the second conductive pattern and comprising a lower gate electrode of the driving transistor;
a first semiconductor pattern disposed on the third conductive pattern and comprising a semiconductor layer of the driving transistor; and
a fourth conductive pattern disposed on the first semiconductor pattern and comprising an upper gate electrode of the driving transistor.

3. The display apparatus of claim 2, wherein the repair line is disposed on a same layer as the first conductive pattern or the second conductive pattern, and
wherein the repair bridge pattern is disposed on a same layer as the third conductive pattern.

4. The display apparatus of claim 2, wherein the first semiconductor pattern comprises an oxide semiconductor material.

5. The display apparatus of claim 2, wherein the first pixel circuit further comprises:
a fifth conductive pattern disposed on the fourth conductive pattern and disposed on a same layer as the first pixel connection electrode; and
a second semiconductor pattern disposed on a same layer as the first semiconductor pattern, connected to the fifth conductive pattern, and comprising a semiconductor layer of an emission control transistor.

6. The display apparatus of claim 5, wherein, in a plan view,
a first portion of the first pixel connection electrode overlaps the second semiconductor pattern, and
a second portion of the first pixel connection electrode overlaps the repair bridge pattern.

7. The display apparatus of claim 6, wherein the first pixel circuit further comprises a second pixel connection electrode disposed on the first pixel connection electrode and connecting the first pixel connection electrode and the light emitting diode to each other, and
wherein the first pixel connection electrode and the second pixel connection electrode electrically connect the second semiconductor pattern and the light emitting diode to each other.

8. The display apparatus of claim 1, further comprising a plurality of voltage lines disposed on the substrate and extending in the first direction or a second direction intersecting the first direction,
wherein the first pixel circuit further comprises a dummy line disposed on a same layer as the repair bridge pattern and extending in the first direction, and
wherein the dummy line is electrically connected to at least one of the plurality of voltage lines.

9. The display apparatus of claim 8, wherein the plurality of voltage lines comprise a reference voltage line extending in the first direction,
wherein the first pixel circuit further comprises a reference transistor connected between the driving transistor and the reference voltage line, and
wherein the dummy line is electrically connected to the reference voltage line.

10. The display apparatus of claim 9, wherein the reference voltage line comprises an upper reference voltage line disposed on a same layer as the first pixel connection electrode, and
wherein the dummy line is connected to the upper reference voltage line through a contact hole.

11. The display apparatus of claim 10, wherein the reference voltage line further comprises a lower reference voltage line disposed under the upper reference voltage line, and
wherein the lower reference voltage line comprises a silicon semiconductor material.

12. The display apparatus of claim 8, wherein the plurality of voltage lines comprise a common voltage line extending in the first direction and electrically connected to the light emitting diode, and
wherein the dummy line is electrically connected to the common voltage line.

13. The display apparatus of claim 8, wherein the plurality of voltage lines comprise a driving voltage line extending in the first direction,
wherein the first pixel circuit further comprises a driving control transistor connected between the driving transistor and the driving voltage line, and
wherein the dummy line is electrically connected to the driving voltage line.

14. The display apparatus of claim 8, wherein the plurality of voltage lines comprise an initialization voltage line extending in the first direction,
wherein the first pixel circuit further comprises:
an emission control transistor connected between the driving transistor and the light emitting diode; and
an initialization transistor connected between the emission control transistor and the initialization voltage line, and
wherein the dummy line is electrically connected to the initialization voltage line.

15. An electronic apparatus comprising:
a substrate;
a first pixel circuit disposed on the substrate and comprising a first transistor and a storage capacitor;
a light emitting diode electrically connected to the first pixel circuit; and
a plurality of voltage lines disposed on the substrate and extending in a first direction,
wherein the first pixel circuit further comprises:
a first conductive pattern comprising a lower gate electrode of the first transistor; and
a dummy line disposed on a same layer as the first conductive pattern and extending in the first direction, and
wherein the dummy line is electrically connected to at least one of the plurality of voltage lines.

16. The electronic apparatus of claim 15, further comprising a data line extending in a second direction intersecting the first direction and connected to the first pixel circuit,
wherein the plurality of voltage lines comprise a reference voltage line extending in the first direction,
wherein the first pixel circuit further comprises:
a second transistor connected between the data line and the first transistor; and
a third transistor connected between the reference voltage line and the first transistor, and
wherein the dummy line is electrically connected to the reference voltage line.

17. The electronic apparatus of claim 15, wherein the plurality of voltage lines comprise a common voltage line extending in the first direction and electrically connected to the light emitting diode, and
wherein the dummy line is electrically connected to the common voltage line.

18. The electronic apparatus of claim 15, wherein the plurality of voltage lines comprise an initialization voltage line extending in the first direction,
wherein the first pixel circuit further comprises a fourth transistor connected between the initialization voltage line and the light emitting diode, and
wherein the dummy line is electrically connected to the initialization voltage line.

19. The electronic apparatus of claim 15, wherein the plurality of voltage lines comprise a driving voltage line extending in the first direction,
wherein the first pixel circuit further comprises a fifth transistor connected between the driving voltage line and the first transistor, and
wherein the dummy line is electrically connected to the driving voltage line.

20. The electronic apparatus of claim 19, wherein a semiconductor layer of the first transistor and a semiconductor layer of the fifth transistor are disposed on different layers.
